(19) United States
(12) Patent Application Publication
(10) Pub. No.: US 2026/0173616 A1
(43) Pub. Date: Jun. 18, 2026

(54) DISPLAY APPARATUS, ELECTRONIC DEVICE INCLUDING THE SAME, AND METHOD OF MANUFACTURING THE DISPLAY APPARATUS

(71) Applicant: Samsung Display Co., LTD., Yongin-si (KR)

(72) Inventors: Hyungil JEON, Yongin-si (KR); Hyungsoo YOON, Yongin-si (KR); Hyejin JOO, Yongin-si (KR); Myunghee HAN, Yongin-si (KR)

(21) Appl. No.: 19/413,201

(22) Filed: Dec. 9, 2025

(30) Foreign Application Priority Data
Dec. 18, 2024 (KR) 10-2024-0190449

(51) Int. Cl. H10H 29/49; H10H 29/01; H10H 29/37

(52) U.S. Cl. CPC H10H 29/49; H10H 29/012; H10H 29/37

(57) ABSTRACT

A display apparatus including a plurality of first island portions and a plurality of first bridge portions connecting the plurality of first island portions includes: a substrate including a base layer overlapping each of the plurality of first island portions and the plurality of first bridge portions; a first mask layer disposed on the base layer to overlap the plurality of first island portions; a pixel circuit layer disposed on the first mask layer; a wiring layer disposed on the base layer to overlap the plurality of first bridge portions; and a light-emitting element disposed on the pixel circuit layer.

This application claims priority to Korean Patent Application No. 10-2024-0190449, filed on Dec. 18, 2024, and all the benefits accruing therefrom under 35 U.S.C. § 119, the content of which in its entirety is herein incorporated by reference.

### BACKGROUND

### (1) Field

Embodiments of the present disclosure relate to a display apparatus, for example, a flexible display apparatus.

### (2) Description of the Related Art

With the development of display apparatuses that visually display electrical signals, various display apparatuses with excellent properties such as thinness, lightness, and low power consumption have been introduced. For example, flexible display apparatuses that can be folded or rolled into a roll shape are being introduced. Recently, research and development are being actively conducted on display apparatuses with various structures, such as stretchable display apparatuses that can be changed into various forms.

### SUMMARY

Embodiments of the present disclosure provide a display apparatus, for example, a flexible display apparatus.

An embodiment of the present disclosure discloses a display apparatus including a plurality of first island portions and a plurality of first bridge portions connecting the plurality of first island portions to each other, the display apparatus including: a substrate including a base layer overlapping each of the plurality of first island portions and the plurality of first bridge portions; a first mask layer disposed on the base layer to overlap the plurality of first island portions; a pixel circuit layer disposed on the first mask layer; a wiring layer disposed on the base layer to overlap the plurality of first bridge portions; and a light-emitting element disposed on the pixel circuit layer.

In an embodiment, the substrate may further include a barrier layer disposed on the first mask layer.

In an embodiment, a width of the first mask layer may be greater than a width of the pixel circuit layer.

In an embodiment, the display apparatus may further include a second mask layer disposed on the base layer to overlap the plurality of first bridge portions.

In an embodiment, the first mask layer and the second mask layer may be arranged in a same layer as each other, and may include a same material as each other.

In an embodiment, a width of the second mask layer may be greater than a width of the wiring layer.

An embodiment of the present disclosure discloses a display apparatus including a plurality of first island portions, and a plurality of first bridge portions connecting the plurality of first island portions to each other, the display apparatus including: a substrate; a pixel circuit layer disposed on the substrate to overlap the plurality of first island portions; a wiring layer disposed on the substrate to overlap the plurality of first bridge portions; and a light-emitting element disposed on the pixel circuit layer, where the substrate includes: a first base layer overlapping the plurality of first island portions; a first barrier layer disposed on the first base layer; a second base layer disposed on the first barrier layer; and a second barrier layer disposed on the second base layer, and the first barrier layer and the second barrier layer surround the second base layer.

In an embodiment, the first barrier layer may include a first first barrier portion supporting a lower surface of the second base layer, and a second first barrier portion extending from the first first barrier portion to the second barrier layer and surrounding the second base layer.

In an embodiment, the second first barrier portion and the second barrier layer may be in contact with each other.

In an embodiment, the second base layer may be accommodated in the second first barrier portion.

In an embodiment, the width of the second barrier layer may be greater than the width of the pixel circuit layer.

An embodiment of the present disclosure discloses an electronic device including a display apparatus that is stretchable and includes a plurality of first island portions and a plurality of first bridge portions connecting the plurality of first island portions to each other, the display apparatus including: a substrate including a base layer overlapping each of the plurality of first island portions and the plurality of first bridge portions; a first mask layer disposed on the base layer to overlap the plurality of first island portions; a pixel circuit layer disposed on the first mask layer; a wiring layer disposed on the base layer to overlap the plurality of first bridge portions; and a light-emitting element disposed on the pixel circuit layer.

An embodiment of the present disclosure discloses a method of manufacturing a display apparatus, the method including: disposing a base layer on a carrier substrate; disposing a first mask layer on the base layer; disposing a second mask layer on the base layer to be spaced apart from the first mask layer in a cross-sectional view; forming a first first opening portion and a second first opening portion in the base layer, by etching a portion of the base layer which is not overlapped with the first mask layer and the second mask layer; arranging a first sacrificial layer within the first first opening portion; disposing a barrier layer on the first mask layer; disposing a pixel circuit layer on the barrier layer; disposing a wiring layer on the base layer to be spaced apart from the pixel circuit layer with the second first opening portion therebetween, in a cross-sectional view; removing the first sacrificial layer; and removing the carrier substrate.

In an embodiment, the method may further include etching a portion of the barrier layer that is overlapped with the first first opening portion.

In an embodiment, the disposing of the pixel circuit layer and the disposing of the wiring layer may be simultaneously performed.

In an embodiment, the width of the first first opening portion may be less than the width of the second first opening portion.

An embodiment of the present disclosure discloses a method of manufacturing a display apparatus, the method including: disposing a first sacrificial layer on a carrier substrate, where the first sacrificial layer defines a first first sacrificial opening portion and a second first sacrificial opening portion; arranging a first base layer within the first first sacrificial opening portion and the second first sacrificial opening portion; disposing a first barrier layer on the first sacrificial layer in a way such that at least a part of the first barrier layer is arranged within the first first sacrificial opening portion; disposing a second base layer on the first base layer to be arranged within the first first sacrificial opening portion and the second first sacrificial opening portion; disposing a second barrier layer on the first barrier layer to cover a portion of the second base layer which is overlapped with the first first sacrificial opening portion; disposing a pixel circuit layer on the second barrier layer to be overlapped with the first first sacrificial opening portion; disposing a wiring layer on the second barrier layer to overlap the second first sacrificial opening portion; removing the first sacrificial layer; and removing the carrier substrate.

In an embodiment, in the disposing of the first barrier layer, the first barrier layer may be in contact with an inner circumferential surface of the first sacrificial layer which defines the first first sacrificial opening portion.

In an embodiment, in the disposing of the second barrier layer, the first barrier layer and the second barrier layer may be in contact with each other, and the first barrier layer and the second barrier layer surround the second base layer.

According to an embodiment of the present disclosure, a display apparatus in which damage due to the concentration of stress may be effectively prevented and which can be stretched in various directions may be provided.

### BRIEF DESCRIPTION OF THE DRAWINGS

FIG. 1 is a perspective view schematically illustrating a display apparatus according to an embodiment of the present disclosure.

FIGS. 2A and 2B are perspective views showing the display apparatus of FIG. 1 in a state where the display apparatus 1 is stretched in a first direction.

FIG. 2C is a perspective view showing the display apparatus of FIG. 1 in a state where the display apparatus 1 is stretched in a second direction.

FIG. 2D is a perspective view showing the display apparatus of FIG. 1 in a state where the display apparatus 1 is stretched in the first direction and the second direction.

FIG. 2E is a perspective view showing the display apparatus of FIG. 1 in a state where the display apparatus 1 is stretched in a third direction.

FIG. 3 is a plan view schematically illustrating a display apparatus according to an embodiment of the present disclosure.

FIG. 4A is an enlarged plan view of a region IV of FIG. 3 as a portion of a display apparatus according to an embodiment of the present disclosure.

FIG. 4B is an enlarged plan view of the region IV of FIG. 3 as a portion of a display apparatus according to an embodiment of the present disclosure.

FIG. 4C is an enlarged plan view of the region IV of FIG. 3 as a portion of a display apparatus according to an embodiment of the present disclosure.

FIG. 5 is a cross-sectional view schematically illustrating a first island portion and a first bridge portion which are arranged in a display area of a display apparatus according to an embodiment of the present disclosure.

FIGS. 6A to 6C are each an equivalent circuit diagram of a sub-pixel of a display apparatus according to an embodiment of the present disclosure.

FIG. 7A is a schematic cross-sectional view of a light-emitting element of a display apparatus according to an embodiment of the present disclosure.

FIG. 7B is a schematic cross-sectional view of a light-emitting element of a display apparatus according to an embodiment of the present disclosure.

FIG. 8A is an enlarged plan view of a first island portion of a display apparatus according to an embodiment of the present disclosure.

FIG. 8B is a plan view showing a layout of wires on the first bridge portion of a display apparatus according to an embodiment of the present disclosure.

FIGS. 9A and 9B are schematic cross-sectional views of a display apparatus according to an embodiment of the present disclosure.

FIG. 10 is a schematic flowchart of a method of manufacturing a display apparatus, according to an embodiment of the present disclosure.

FIGS. 11A to 11J are schematic cross-sectional views of a display apparatus according to an embodiment of the present disclosure.

FIG. 12 is a schematic cross-sectional view of a display apparatus according to an embodiment of the present disclosure.

FIG. 13 is a schematic flowchart of a method of manufacturing a display apparatus, according to an embodiment of the present disclosure.

FIGS. 14A to 14H are schematic cross-sectional views of a display apparatus according to an embodiment of the present disclosure.

FIG. 15A is a schematic perspective view of an electronic device including a display apparatus according to an embodiment of the present disclosure.

FIG. 15B is a block diagram schematically showing an electronic device including a display apparatus according to an embodiment of the present disclosure.

FIGS. 16A to 16D are each a perspective view schematically illustrating embodiments of an electronic device including a display apparatus according to an embodiment of the present disclosure.

FIGS. 17A to 17E are each a perspective view schematically illustrating an electronic device according to an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

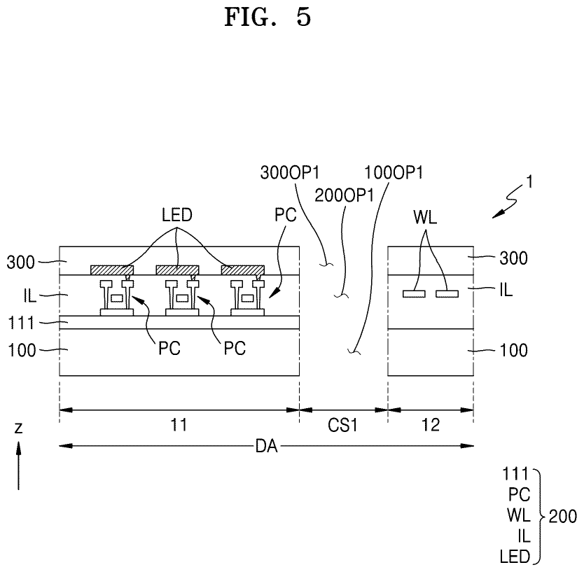

In the specification, when it is referred to as “in a plan view,” this means a plane viewed in a direction perpendicular to a substrate 100 (see FIG. 5). In other words, “A and B separated from each other in a plan view” may mean “A and B separated from each other when viewed in the direction perpendicular to the substrate 100 (see FIG. 5).”

In the specification, when it is referred to as “in a cross-sectional vie w,” this means a plane cut in in the direction perpendicular to the substrate 100 (see FIG. 5).” In other words, “A and B separated from each other in a cross-sectional view” may mean “A and B separated from each other when viewed in the direction perpendicular to the substrate 100 (see FIG. 5).”

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

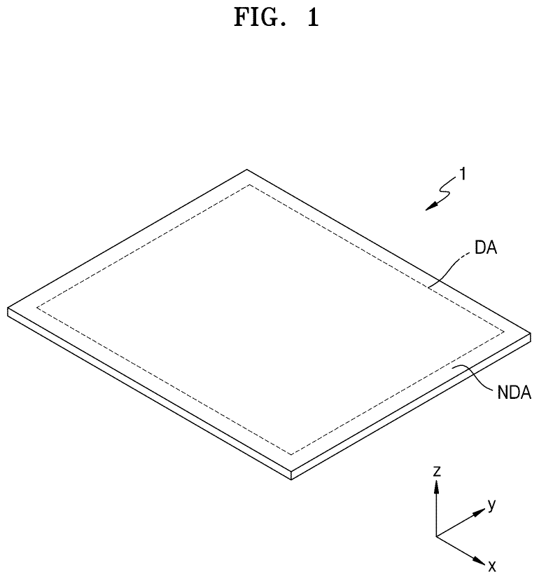

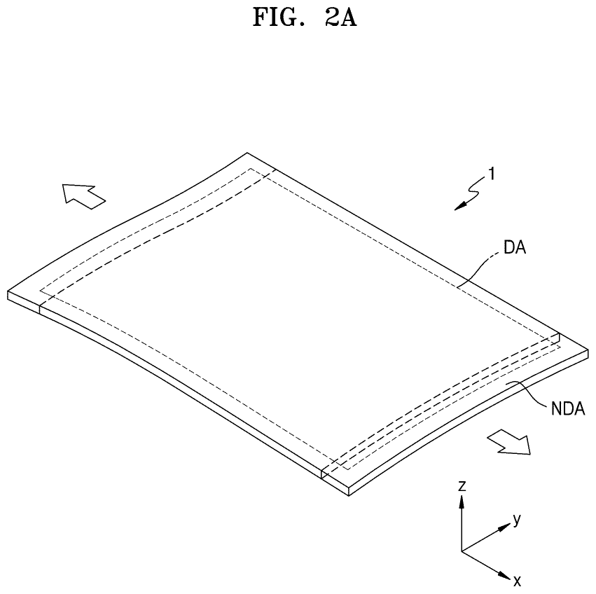

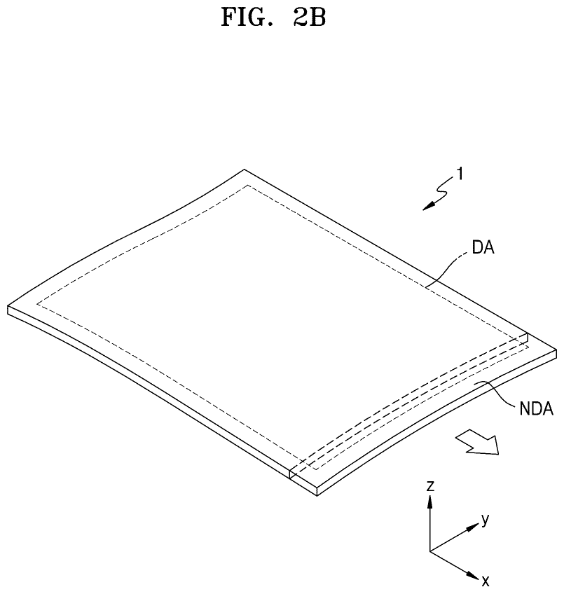

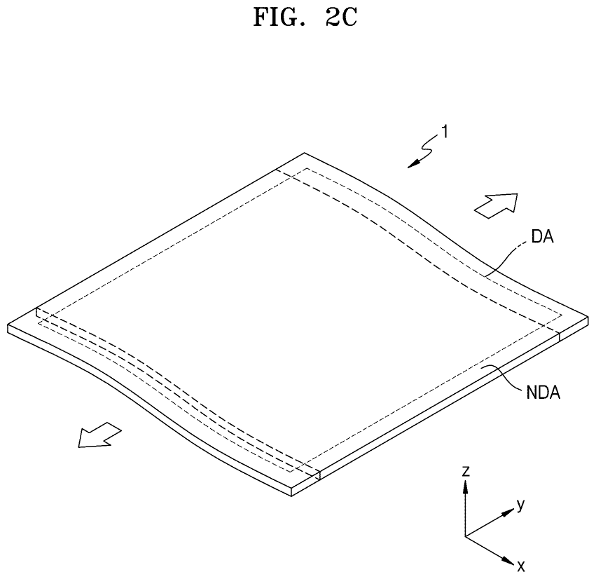

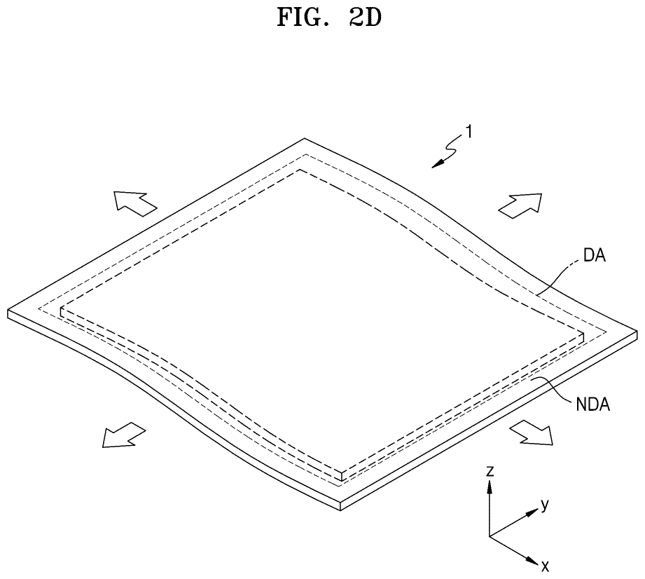

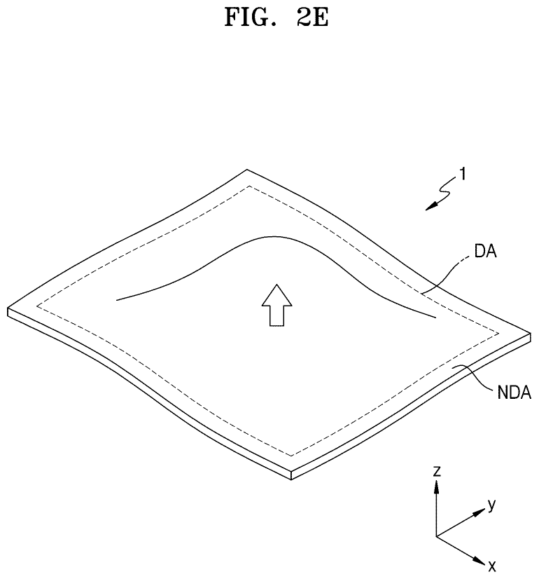

FIG. 1 is a perspective view schematically illustrating a display apparatus 1 according to an embodiment of the present disclosure. FIGS. 2A and 2B are perspective views showing the display apparatus 1 of FIG. 1 in a state where the display apparatus 1 is stretched in a first direction. FIG. 2C is a perspective view showing the display apparatus 1 of FIG. 1 in a state where the display apparatus 1 is stretched in a second direction. FIG. 2D is a perspective view showing the display apparatus 1 of FIG. 1 in a state where the display apparatus 1 is stretched in the first direction and the second direction. FIG. 2E is a perspective view showing the display apparatus 1 of FIG. 1 in a state where the display apparatus 1 is stretched in a third direction.

Referring to FIG. 1, an embodiment of the display apparatus 1 may include a display area DA and a non-display area NDA. The display area DA may include a plurality of pixels. The display apparatus 1 may provide a certain image by using light emitted from the plurality of pixels. The non-display area NDA may be arranged outside the display area DA. The non-display area NDA may entirely surround the display area DA. The non-display area NDA may not include any pixel.

The display apparatus 1 may stretch or shrink in various directions. The display apparatus 1 may be stretched in a first direction (e.g., a +x direction and/or a −x direction) by an external force applied by an external object or a user. In an embodiment, as illustrated in FIGS. 2A and 2B, the display area DA and/or the non-display area NDA of the display apparatus 1 may be stretched in the first direction (e.g., the +x direction and/or the −x direction). For example, the display area DA and/or the non-display area NDA of the display apparatus 1 may be stretched in the +x direction and the −x direction, as illustrated in FIG. 2A, or may be stretched in the +x direction with one side of the display apparatus 1 fixed, as illustrated in FIG. 2B.

The display apparatus 1 may be stretched in a second direction (e.g., a +y direction and/or a −y direction) by an external force applied by an external object or a user. In an embodiment, as illustrated in FIG. 2C, the display area DA and/or the non-display area NDA of the display apparatus 1 may be stretched in the +y direction and the −y direction. In another embodiment, the display area DA and/or the non-display area NDA of the display apparatus 1 may be stretched in the +y direction or the −y direction with one side of the display apparatus 1 fixed.

The display apparatus 1 may be stretched by an external force applied by an external object or a part of a human body in a plurality of directions, for example, the first direction (e.g., the +x direction and/or the −x direction) and in the second direction (e.g., the +y direction and/or the −y direction). In an embodiment, as illustrated in FIG. 2D, the display area DA and/or the non-display area NDA of the display apparatus 1 may be stretched in the ±x direction and the ±y direction.

The display apparatus 1 may be stretched in a third direction (e.g., a +z direction or a −z direction) by an external force applied by an external object or a part of a human body. In an embodiment, FIG. 2E illustrates that a part of the display apparatus 1, for example, a partial area of the display area DA, protrudes in the z direction. In another embodiment, a part of the display apparatus 1, for example, a partial area of the display area DA, may protrude in the +z direction (or may be recessed in the −z direction).

FIGS. 2A to 2E illustrate an embodiment where the display apparatus 1 is stretched (or stretchable) in the first direction, the second direction, and/or the third direction, but the disclosure is not limited thereto. In another embodiment, the display apparatus 1 may be transformed into various amorphous shapes by bending or twisting about two or more axes.

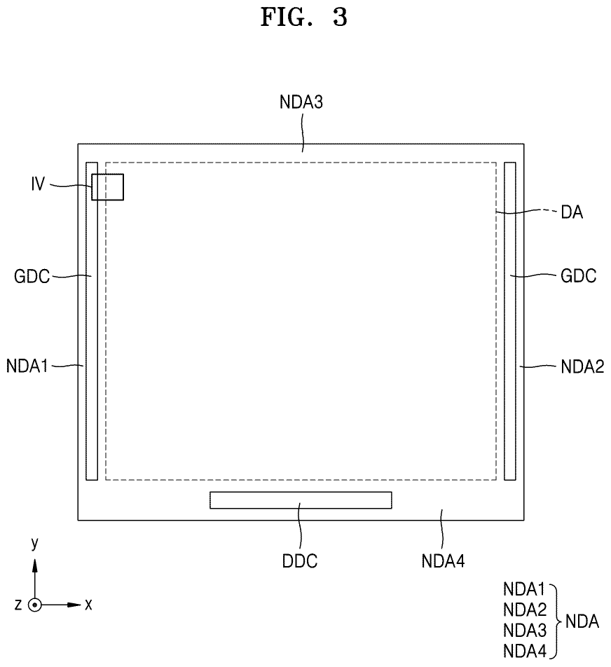

FIG. 3 is a plan view schematically illustrating the display apparatus 1 according to an embodiment of the present disclosure.

In an embodiment, a plurality of pixels may be arranged in the display area DA of the display apparatus 1. Each pixel may include sub-pixels that emit light of different colors. A light-emitting element corresponding to each sub-pixel may be arranged in the display area DA. A circuit for providing electrical signals to the light-emitting elements arranged in the display area DA and transistors electrically connected to the light-emitting elements may be located in the non-display area NDA around the display area DA. A gate drive circuit GDC may be arranged in each of a first non-display area NDA1 and a second non-display area NDA2 which are arranged on the opposite sides with respect to the display area DA. The gate drive circuit GDC may include drivers for providing electrical signals to gate electrodes of transistors respectively electrically connected to the light-emitting elements. FIG. 3 illustrates an embodiment where the gate drive circuit GDC is arranged in each of the first non-display area NDA1 and the second non-display area NDA2, but the disclosure is not limited thereto. In another embodiment, the gate drive circuit GDC may be arranged in any one of the first non-display area NDA1 and the second non-display area NDA2.

A data drive circuit DDC may be arranged in a third non-display area NDA3 and/or a fourth non-display area NDA4 that connect the first non-display area NDA1 to the second non-display area NDA2. In an embodiment, as illustrated in FIG. 3, the data drive circuit DDC may be arranged in the fourth non-display area NDA4. In another embodiment, the data drive circuit DDC may be arranged in each of the third non-display area NDA3 and the fourth non-display area NDA4.

FIG. 3 illustrates an embodiment where the data drive circuit DDC is arranged in the fourth non-display area NDA4 of the display apparatus 1, but the disclosure is not limited thereto. In another embodiment, the display apparatus 1 may further include a flexible circuit board (not shown) that is electrically connected through a terminal portion (not shown) arranged in the fourth non-display area NDA4, and the data drive circuit DDC may be arranged on the flexible circuit board described above.

In some embodiments, the elongation of the non-display area NDA may be equal to or less than the elongation of the display area DA. In an embodiment, the elongation of the non-display area NDA may vary for each area. In an embodiment, for example, while the first non-display area NDA1, the second non-display area NDA2, and the third non-display area NDA3 may have substantially the same elongation, the elongation of the fourth non-display area NDA4 may be less than the elongation of each of the first non-display area NDA1, the second non-display area NDA2, and the third non-display area NDA3. In the specification, the elongation is a value representing a change (ΔL/L) in length in which the display apparatus 1 can be stretched without physical damage to the display apparatus 1 when an external force applies to the display apparatus 1. Here, ΔL denotes a change amount of the length of the display apparatus, and L denotes the initial length of the display apparatus.

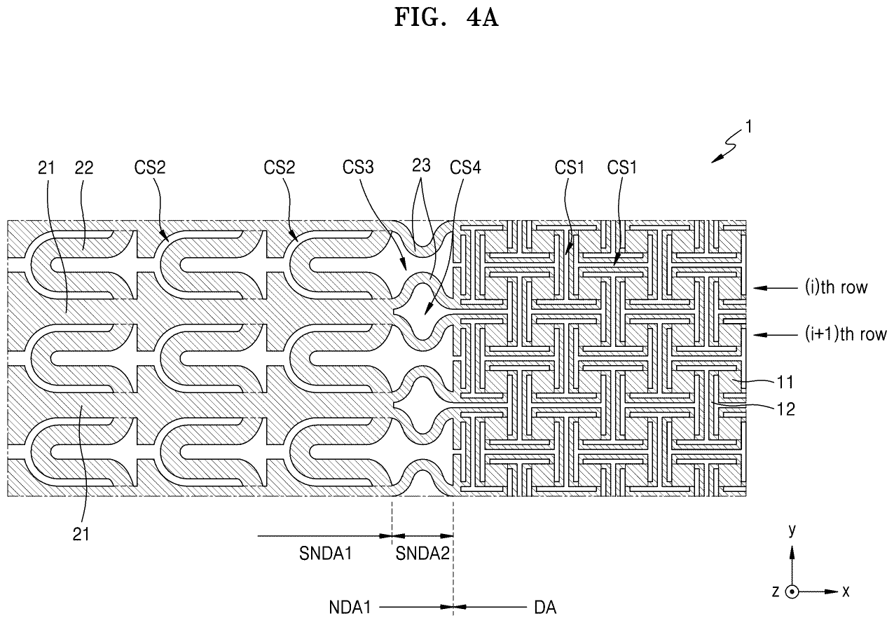

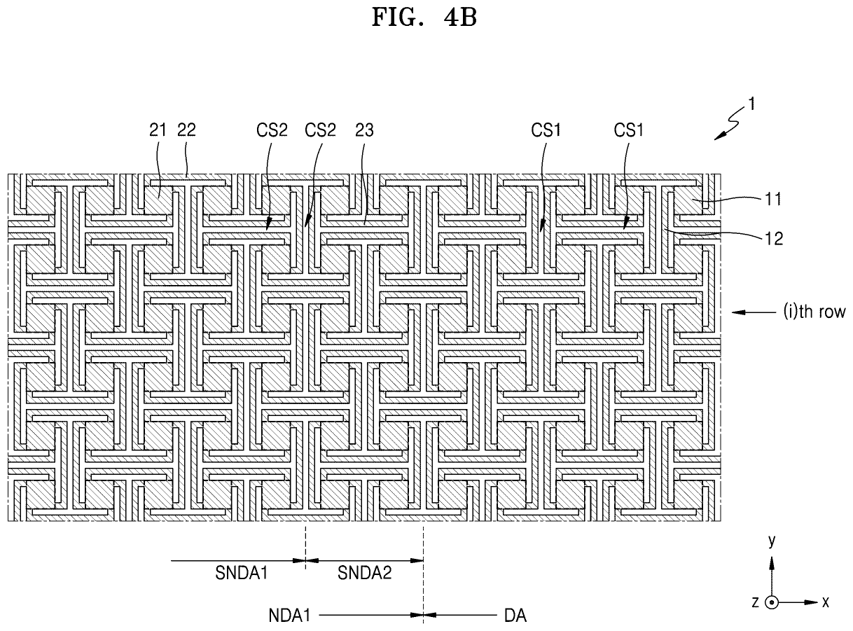

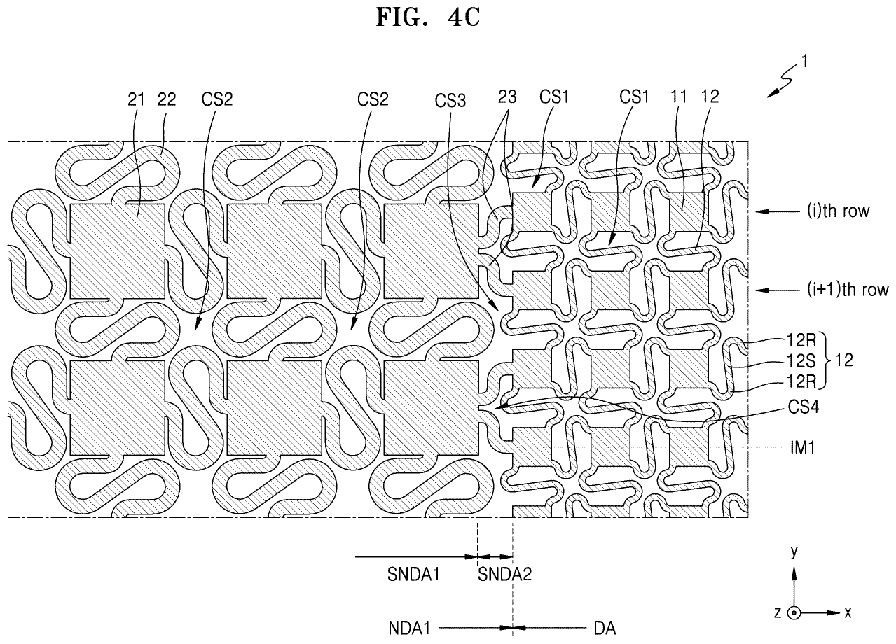

FIG. 4A is an enlarged plan view of a region IV of FIG. 3 as a portion of the display apparatus 1 according to an embodiment of the present disclosure.

Referring to FIG. 4A, an embodiment of the display apparatus 1 may include, in the display area DA, first island portions 11 separated from each other in a first direction (e.g., an x direction or a −x direction) and a second direction (e.g., a y direction or a −y direction), and first bridge portions 12 connecting (or connected between) the first island portions 11 adjacent thereto to each other.

Each of the first island portions 11 may be connected to the plurality of first bridge portions 12. In an embodiment, for example, each of the first island portions 11 may be connected to four first bridge portions 12. Two first bridge portions 12 of the four first bridge portions 12 may be arranged on the both opposing sides of each of the first island portions 11 in the first direction (e.g., the x direction or the-x direction), and the other two first bridge portions 12 of the four first bridge portions 12 may be arranged on the both opposing sides of each of the first island portions 11 in the second direction (e.g., the y direction or the-y direction). In an embodiment, four first bridge portions 12 may be respectively connected to four sides of each of the first island portions 11. The four first bridge portions 12 may be respectively adjacent to the corners of each of the first island portions 11.

The first bridge portions 12 may be separated from each other by a first opening portion CS1 located between the first bridge portions 12. In an embodiment, the first opening portion CS1 of a roughly H (or H-like) shape and the first opening portion CS1 of a roughly I (I-like) shape obtained by rotating the H shape described above by about 90° may be alternately and repeatedly arranged in the first direction (e.g., the x direction or the −x direction) and the second direction (e.g., the y direction or the −y direction). Both end portions of each of the first bridge portions 12 may be connected to the respective first island portions 11 adjacent thereto, and one side of each of the first bridge portions 12 may be separated by the first opening portion CS1 from one side of each of the first island portions 11 adjacent thereto and/or one side of another first bridge portion 12.

The display apparatus 1 may include, in the non-display area, for example, the first non-display area NDA1 illustrated in FIG. 4A, second island portions 21 separated from each other and second bridge portions 22 connecting (or connected between) the second island portions 21 adjacent thereto to each other.

Each of the second island portions 21 may extend in the first direction (e.g., the x direction or the −x direction). The second island portions 21 may be separated from each other in the second direction (e.g., the y direction or the −y direction) crossing the first direction (e.g., the x direction or the −x direction). Each of the second island portions 21 may include drivers of the gate drive circuit GDC of FIG. 2 described with reference to FIG. 3.

Each of the second bridge portions 22 may have a serpentine shape. The length of each of the second bridge portions 22 may be greater than the minimum distance between adjacent second island portions 21 in the second direction (e.g., the y direction or the-y direction). In an embodiment, each of the second bridge portions 22 may have a roughly omega (Ω) (or Ω-like) shape convex toward the first direction (e.g., the x direction or the −x direction). The second bridge portions 22 may be arranged between the second island portions 21 adjacent thereto and may be separated from each other.

The second bridge portions 22 between the second island portions 21 adjacent thereto may be separated from each other by a second opening portion CS2. The second opening portions CS2 and the second bridge portions 22 may be alternately arranged in the first direction (e.g., the x direction or the −x direction) between the second island portions 21 adjacent thereto. The second opening portions CS2 may have a same shape as each other. Both end portions of each of the second bridge portions 22 may be connected to the second island portions 21 adjacent thereto, and one side of each of the second bridge portions 22 may be separated by the second opening portion CS2 from one side of adjacent second island portion 21 and/or one side of another second bridge portion 22.

Any one second island portion 21 arranged in the first non-display area NDA1 may correspond to the first island portions 11 arranged in a plurality of rows in the display area DA. In an embodiment, for example, any one second island portion 21 arranged in the first non-display area NDA1 may correspond to the first island portions 11 arranged in an (i)th row and the first island portions 11 arranged in an (i+1)th row, in the display area DA (here, i is a positive number greater than 0). FIG. 4A illustrates an embodiment where one second island portion 21 corresponds to two rows of the first island portions 11, but the disclosure is not limited thereto. In another embodiment, any one second island portion 21 arranged in the first non-display area NDA1 may correspond to n rows of the first island portions 11 arranged in the display area DA (here, n is a positive number of 3 or more).

The non-display area, for example, the first non-display area NDA1, may include a first sub-non-display area SNDA1, in which the second island portions 21 and the second bridge portions 22 described above are arranged, and a second sub-non-display area SNDA2 between the first sub-non-display area SNDA1 and the display area DA. Third bridge portions 23 to connect the display area DA to the first sub-non-display area SNDA1 may be arranged in the second sub-non-display area SNDA2. One end portion of each of the third bridge portions 23 may be connected to each of the second island portions 21 and/or each of the second bridge portions 22, and the other end portion of each of the third bridge portions 23 may be connected to each of the first island portions 11 and/or each of the first bridge portions 12.

Each of the third bridge portions 23 may have a serpentine shape. In an embodiment, the shape of each of the third bridge portions 23 may be different from the shape of each of the first bridge portions 12 and each of the second bridge portions 22. In an embodiment, as illustrated in FIG. 4A, each of the third bridge portions 23 may have a roughly omega (Ω) shape convex toward the second direction (e.g., the y direction or the −y direction). In an embodiment, one of the third bridge portions 23 adjacent to each other in the second direction (e.g., the y direction or the −y direction) is convex in the y direction and another of the third bridge portions 23 adjacent to each other in the second direction (e.g., the y direction or the −y direction) is convex in the −y direction, forming a symmetrical structure. A structure in which a third opening portion CS3 and a fourth opening portion CS4 having different shapes are repeated may be provided between the third bridge portions 23. The width of each of the third bridge portions 23 may be different from each of the width of each of the first bridge portions 12 and the width of each of the second bridge portions 22. In an embodiment, the width of each of the third bridge portions 23 may be greater than the width of each of the first bridge portions 12 and less than the width of each of the second bridge portions 22.

FIG. 4A shows an embodiment where each of the second island portions 21 and each of the second bridge portions 22 in the non-display area, for example, the first non-display area NDA1, have different shapes from each of the first island portions 11 and each of the first bridge portions 12 in the display area DA, respectively. In another embodiment, of the present disclosure, each of the second island portions 21 and each of the second bridge portions 22 in non-display area may a the same shape as each of the first island portions 11 and each of the first bridge portions 12 in the display area DA.

FIG. 4B is an enlarged plan view of the region IV of FIG. 3 as a portion of the display apparatus 1 according to an embodiment of the present disclosure.

Referring to FIG. 4B, in an embodiment, the display apparatus 1 includes, in the display area DA, the first island portions 11 separated from each other and the first bridge portions 12 separated from each other by the first opening portion CS1 and connecting the first island portions 11 adjacent thereto. The structure of the display area DA of FIG. 4B may be the same as the structure of the display area DA described above with reference to FIG. 4A.

The display apparatus 1 may include the second island portions 21 and the second bridge portions 22 which are arranged in the non-display area, for example, the first non-display area NDA1. In an embodiment, the second island portions 21 and the second bridge portions 22 may respectively have substantially the same shapes as the first island portions 11 and the first bridge portions 12.

The second island portions 21 may be separated from each other in the non-display area, for example, the first non-display area NDA1, in the first direction (e.g., the x direction or the-x direction) and the second direction (e.g., the y direction or the-y direction). The second bridge portions 22 may respectively connect the second island portions 21 adjacent thereto. The second bridge portions 22 may be separated from each other by the second opening portion CS2 located between the second bridge portions 22.

The second opening portion CS2 may have substantially the same shape as the first opening portion CS1. In an embodiment, for example, the second opening portion CS2 of an approximately H shape and the second opening portion CS2 of a roughly I shape may be alternately and repeatedly arranged in the non-display area, for example, the first non-display area NDA1. Both end portions of each of the second bridge portions 22 may be respectively connected to the second island portions 21 adjacent thereto, and one side of each of the second bridge portions 22 may be separated by the second opening portion CS2 from one side of any one second island portion 21 adjacent thereto and/or one side of another second bridge portion 22.

Each of the second island portions 21 may be connected to four second bridge portions 22. Each of the second island portions 21 may include drivers of the gate drive circuit GDC of FIG. 2 described with reference to FIG. 3.

The second island portions 21 arranged in any one row in the first non-display area NDA1 may correspond to the first island portions 11 arranged in any one row in the display area DA. In an embodiment, for example, the second island portions 21 arranged in the (i)th row in the first direction (e.g., the x direction or the −x direction) in the first non-display area NDA1 may correspond to the first island portions 11 arranged in the same row, for example, the (i)th row, in the display area DA (here, i is a positive number greater than 0).

The display apparatus 1 may include the third bridge portions 23 arranged in the second sub-non-display area SNDA2 to connect the display area DA to the first sub-non-display area SNDA1. The non-display area, for example, the first non-display area NDA1 may include the first sub-non-display area SNDA1 in which the second island portions 21 and the second bridge portions 22 are arranged, and the second sub-non-display area SNDA2 including the third bridge portions 23 and located between the first sub-non-display area SNDA1 and the display area DA. Each of the third bridge portions 23 may be substantially the same as each of the first bridge portions 12 and each of the second bridge portions 22. In an embodiment, for example, the width of each of the third bridge portions 23 may be the same as the width of each of the first bridge portions 12 and the width of each of the second bridge portions 22.

FIG. 4C is an enlarged plan view of the region IV of FIG. 3 as a portion of a display apparatus according to an embodiment of the present disclosure.

Referring to FIG. 4C, in an embodiment, the display apparatus 1 may include, in the display area DA, the first island portions 11 separated from each other in the first direction (e.g., the x direction or the-x direction) and the second direction (e.g., the y direction or the-y direction), and the first bridge portions 12 connecting the first island portions 11 adjacent thereof.

The first bridge portions 12 may be separated from each other by the first opening portion CS1 arranged between the first bridge portions 12. In an embodiment, each of the first bridge portions 12 may have a serpentine shape. In an embodiment, for example, as illustrated in FIG. 4C, each of the first bridge portions 12 may have a roughly ‘alphabet S’ shape including two round parts 12R and a straight line part 12S between the two round parts 12R.

Each of the first island portions 11 may be connected to the first bridge portions 12. In an embodiment, for example, each of the first island portions 11 may be connected to four first bridge portions 12. Two first bridge portions 12 of the four first bridge portions 12 may be arranged on the both sides of each of the first island portions 11 in the first direction (e.g., the x direction or the-x direction), and the other two first bridge portions 12 of the four first bridge portions 12 may be arranged on the both sides of each of the first island portions 11 in the second direction (e.g., the y direction or the-y direction). The four first bridge portions 12 may be respectively connected to four sides of each of the first island portions 11. The four first bridge portions 12 may be respectively adjacent to corners of each of the first island portions 11.

The display apparatus 1 may include, in the non-display area, for example, the first non-display area NDA1 illustrated in FIG. 4C, the second island portions 21 separated from each other in the first direction (e.g., the x direction or the −x direction) and the second direction (e.g., the y direction or the-y direction), and the second bridge portions 22 connecting the second island portions 21 adjacent thereto.

Each of the second bridge portions 22 may be separated by the second opening portion CS2 located between the second bridge portions 22. In an embodiment, each of the second bridge portions 22 may have a serpentine shape. In an embodiment, for example, as illustrated in FIG. 4C, each of the second bridge portions 22 may have a roughly S (or S-like) shape. The size and/or width of each of the second bridge portions 22 may be different from the size and/or width of each of the first bridge portions 12. In an embodiment, for example, the size and/or width of each of the second bridge portions 22 may be greater than the size and/or width of each of the first bridge portions 12. The radius of curvature of a rounded part of each of the second bridge portions 22 may be different from the radius of curvature of a rounded part of each of the first bridge portions 12. In an embodiment, for example, radius of curvature of a rounded part of each of the second bridge portions 22 may be greater from the radius of curvature of a rounded part of each of the first bridge portions 12.

Each of the second island portions 21 may be connected to the second bridge portions 22. Each of the second island portions 21 may be connected to four second bridge portions 22. Two second bridge portions 22 of the four second bridge portions 22 may be arranged on both sides of each of the second island portions 21 in the first direction (e.g., the x direction or the-x direction), and the other two second bridge portions 22 of the four second bridge portions 22 may be arranged on both sides of each of the second island portions 21 in the second direction (e.g., the y direction or the-y direction). In an embodiment, four second bridge portions 22 may be respectively connected to four sides of each of the second island portions 21. Each of the second bridge portions 22 may be connected to a central portion of one side of each of the second island portions 21.

The second island portions 21 arranged in any one row in the first non-display area NDA1 may correspond to the first island portions 11 arranged in a plurality of rows in the display area DA. In an embodiment, for example, the second island portions 21 arranged in the (i)th row in the first direction (e.g., the x direction or the-x direction) in the first non-display area NDA1 may correspond to the first island portions 11 arranged in the (i)th row and the first island portions 11 arranged in the (i+1)th row, in the display area DA (here, i is a positive number greater than 0). In another embodiment, the second island portions 21 of any one row may correspond to n rows of the first island portions 11 (here, n is a positive number of 3 or more).

The non-display area, for example, the first non-display area NDA1 may include the first sub-non-display area SNDA1 in which the second island portions 21 and the second bridge portions 22 described above are arranged, and the second sub-non-display area SNDA2 between the first sub-non-display area SNDA1 and the display area DA. The third bridge portions 23 to connect the display area DA to the first sub-non-display area SNDA1 may be arranged in the second sub-non-display area SNDA2. One end portion of each of the third bridge portions 23 may be connected to each of the second island portions 21, and the other end portion of each of the third bridge portions 23 may be connected to each of the first island portions 11. In an embodiment, for example, one end portion of each of the third bridge portions 23 may be connected to a central portion of one side of each of the second island portions 21, and the other end portion of each of the third bridge portions 23 may be connected to a central portion of one side of each of the first island portions 11.

Each of the third bridge portions 23 may have a serpentine shape. In an embodiment, the shape of each of the third bridge portions 23 may be different from the shape of each of the first bridge portions 12 and each of the second bridge portions 22. The width of each of the third bridge portions 23 may be different from each of the width of each of the first bridge portions 12 and the width of each of the second bridge portions 22. The width of each of the third bridge portions 23 may be greater than the width of each of the first bridge portions 12 and less than the width of each of the second bridge portions 22. The third opening portion CS3 and the fourth opening portion CS4 having different shapes may be alternately arranged between the third bridge portions 23 in the second direction (e.g., the y direction or the-y direction).

FIG. 5 is a cross-sectional view schematically illustrating the first island portion 11 and the first bridge portion 12, which are arranged in the display area DA of the display apparatus 1 according to an embodiment of the present disclosure.

Referring to FIG. 5, in an embodiment of the first island portion 11 and the first bridge portion 12 arranged in the display area DA may be separated from each other with the first opening portion CS1 therebetween. The first island portion 11 may include the light-emitting elements LED and circuits, for example, pixel driving circuit portions PC, which are electrically connected to the light-emitting elements to drive the light-emitting elements, and the first bridge portion 12 may include wires WL electrically connected to the pixel driving circuit portions PC arranged in each of the first island portions 11 adjacent thereto.

In the first island portion 11, a buffer layer 111 including an inorganic insulating material may be disposed on a substrate 100, and the pixel driving circuit portions PC may be disposed on the buffer layer 111. An insulating layer IL including inorganic insulating material and/or organic insulating material may be arranged between the pixel driving circuit portions PC and the light-emitting elements LED. The light-emitting elements LED may be disposed on the insulating layer IL, and may be electrically connected to the pixel driving circuit portions PC corresponding thereto. The light-emitting elements LED may emit light of different colors or light of a same color. In an embodiment, the light-emitting elements LED may respectively emit light of red, green, and blue colors. In some embodiments, the light-emitting elements LED may emit white light. In another embodiment, the light-emitting elements LED may respectively emit light of red, green, blue, and white colors.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multilayer structure including a base layer including the polymer resin described above and a barrier layer including an inorganic insulating material. The substrate 100 including the polymer resin may be flexible, rollable, and bendable.

In an embodiment, as illustrated in FIG. 5, three pixel driving circuit portions PC may be arranged in the first island portion 11 and three light-emitting elements LED are respectively connected to the pixel driving circuit portions PC, but the disclosure is not limited thereto. In another embodiment, the numbers of the pixel driving circuit portions PC and the light-emitting elements LED arranged in the first island portion 11 may be one, two, four, or more.

An encapsulation layer 300 may be disposed on the light-emitting elements LED, and may protect the light-emitting elements LED from an external force and/or infiltration of moisture. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material, for example, photoresist.

In the first bridge portion 12, the insulating layer IL including an organic insulating material may be disposed on the substrate 100. In the first bridge portion 12 that is relatively deformed further than the first island portion 11 when the display apparatus 1 is stretched, a layer including an inorganic insulating material that easily generates cracks when deformed may not be present or not included in the insulating layer IL.

In an embodiment, the substrate 100 corresponding to the first bridge portion 12 may have a same stack structure as the substrate 100 corresponding to the first island portion 11. In an embodiment, the substrate 100 corresponding to the first bridge portion 12 and the substrate 100 corresponding to the first island portion 11 may be a polymer resin layer formed together in the same process. In another embodiment, the substrate 100 corresponding to the first bridge portion 12 may have a stack structure different from the substrate 100 corresponding to the first island portion 11. In some embodiments, the substrate 100 corresponding to the first island portion 11 may have a multilayer structure including a base layer including polymer resin and a barrier layer including an inorganic insulating material, and the substrate 100 corresponding to the first bridge portion 12 may have a structure of a polymer resin layer without a layer including an inorganic insulating material.

The wires WL of the first bridge portion 12 may be, as described above, a signal line (e.g., a gate line, a data line, etc.) for providing electrical signals or a voltage line (e.g., a driving voltage line, an initialization voltage line, etc.) for providing voltage to the transistors included in the pixel driving circuit portions PC of the first island portion 11. The encapsulation layer 300 may be arranged in the first bridge portion 12. In another embodiment, the encapsulation layer 300 may not be present in the first bridge portion 12.

Referring to FIGS. 4A to 4C and 5, a portion of the substrate 100 corresponding to the first island portion 11 and a portion of the substrate 100 corresponding to the first bridge portion 12 may be connected to each other. In other words, the plan views illustrated above in FIGS. 4A to 4C may be substantially the same as a plan view of the substrate 100 in FIG. 5. In other words, the substrate 100 may include an area (or a portion) corresponding to the first island portion 11 and an area (or a portion) corresponding to the first bridge portion 12, and an opening 100OP1 having a same shape as the first opening portion CS1 may be defined through the substrate 100.

Similarly, the encapsulation layer 300 corresponding to the first island portion 11 and the encapsulation layer 300 corresponding to the first bridge portion 12 may be connected to each other. For example, the plan views illustrated above in FIGS. 4A to 4C may be substantially the same as a plan view of the encapsulation layer 300. In other words, the encapsulation layer 300 may include an area (or a portion) corresponding to the first island portion 11 and an area (or a portion) corresponding to the first bridge portion 12, and an opening 300OP1 having the same shape as the first opening portion CS1 may be defined through the encapsulation layer 300.

A circuit-light-emitting element layer 200 between the substrate 100 and the encapsulation layer 300 may include the buffer layer 111, the pixel driving circuit portions PC, the wire WL, the insulating layer IL, and the light-emitting elements LED. Similar to the substrate 100, the plan views illustrated above in FIGS. 4A to 4C may be substantially the same as a plan view of the circuit-light-emitting element layer 200. In other words, the circuit-light-emitting element layer 200 may be provided with an opening 200OP1 having the same shape as the first opening portion CS1.

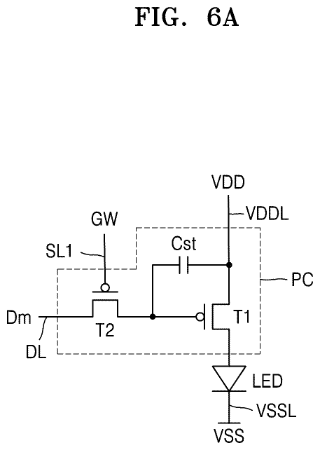

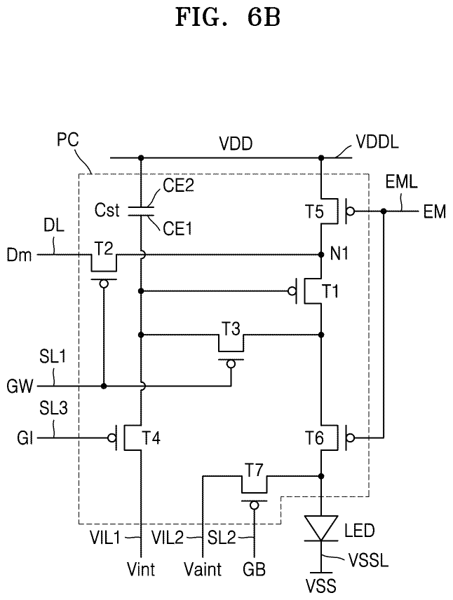

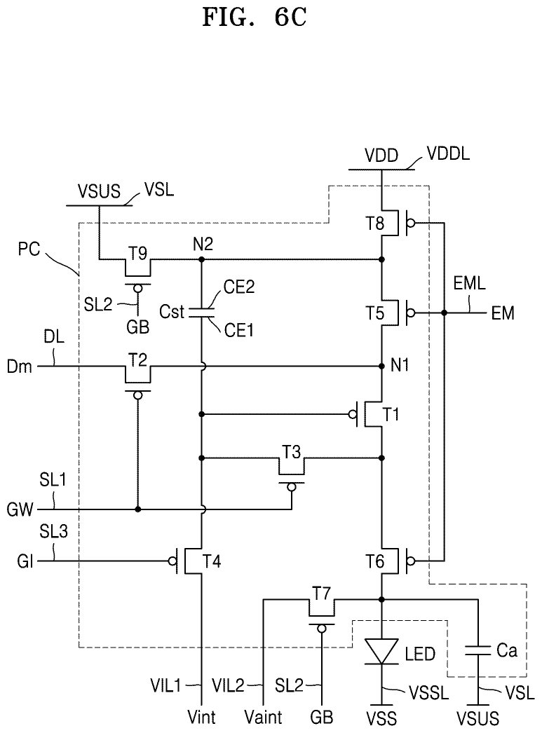

FIGS. 6A to 6C are each an equivalent circuit diagram of the sub-pixel of the display apparatus 1 according to an embodiment of the present disclosure.

Referring to FIG. 6A, in an embodiment, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1 and a data line DL, and the voltage line may include a first voltage line VDDL.

The second transistor T2 may be electrically connected to the first scan line SL1 and the data line DL. The first scan line SL1 may provide (or transmit) a first scan signal GW to a gate electrode of the second transistor T2. The second transistor T2 may transmit a data signal Dm input thereto through the data line DL to the first transistor T1, in response to the first scan signal GW input through the first scan line SL1.

The storage capacitor Cst may be electrically connected to the second transistor T2 and the first voltage line VDDL, and may store a voltage corresponding to a difference between the voltage transmitted from the second transistor T2 and a first power voltage VDD received through the first voltage line VDDL.

The first transistor T1, as a driving transistor, may control a driving current flowing in the light-emitting element LED. The first transistor T1 may be connected to the first voltage line VDDL and the storage capacitor Cst. The first transistor T1 may control the driving current flowing from the first voltage line VDDL to the light-emitting element LED, in response to a voltage value stored in the storage capacitor Cst. The light-emitting element LED may emit light with a certain luminance corresponding to the driving current. A first electrode of the light-emitting element LED may be electrically connected to the first transistor T1, and a second electrode of the light-emitting element LED may be electrically connected to the second voltage line VSSL through which a second power voltage VSS is supplied.

FIG. 6A illustrates an embodiment where the pixel driving circuit portion PC includes two transistors and one storage capacitor, but in another embodiment, the pixel driving circuit portion PC may include three or more transistors.

Referring to FIG. 6B, in another embodiment, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include a gate line, such as the first scan line SL1, a second scan line SL2, a third scan line SL3, and an emission control line EML, and the data line DL. The voltage lines may include first and second initialization voltage lines VL1 and VL2 and the first voltage line VDDL.

The first voltage line VDDL may transmit the first power voltage VDD to the first transistor T1. The first initialization voltage line VIL1 may transmit a first initialization voltage Vint for initializing the first transistor T1 to the pixel driving circuit portion PC. The second initialization voltage line VIL2 may transmit a second initialization voltage Vaint for initializing the first electrode of the light-emitting element LED, to the pixel driving circuit portion PC.

The first transistor T1 may be electrically connected to the first voltage line VDDL via the fifth transistor T5, and to the light-emitting element LED via the sixth transistor T6. The first transistor T1, which serves as a driving transistor, may receive the data signal Dm based on a switching operation of the second transistor T2 and supply a driving current to the light-emitting element LED.

The second transistor T2, as a data write transistor, may be electrically connected to the first scan line SL1 and the data line DL. The second transistor T2 may be electrically connected to the first voltage line VDDL via the fifth transistor T5. The second transistor T2 may be turned on in response to the first scan signal GW received through the first scan line SL1 to perform a switching operation of transmitting the data signal Dm received through the data line DL to a first node N1.

The third transistor T3 may be electrically connected to the first scan line SL1 and electrically connected to the light-emitting element LED via the sixth transistor T6. The third transistor T3 may be turned on in response to the first scan signal GW received through the first scan line SL1 to diode-connect the first transistor T1, that is, to connect the first transistor T1 in a diode form.

The fourth transistor T4, as a first initialization transistor, may be electrically connected to the third scan line SL3 and the first initialization voltage line VIL1. The fourth transistor T4 may be turned on in response to a third scan signal GI received through the third scan line SL3 to transmit the first initialization voltage Vint received through the first initialization voltage line VIL1 to a gate electrode of the first transistor T1, thereby initializing the voltage of the gate electrode of the first transistor T1. The third scan signal GI may correspond to a first scan signal of another pixel driving circuit portion arranged in the previous row of the corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, and may be simultaneously turned on in response to an emission control signal EM received through the emission control line EML to form a current path through which a driving current flows in a direction from the first voltage line VDDL to the light-emitting element LED.

The seventh transistor T7, as a second initialization transistor, may be electrically connected to the second scan line SL2, the second initialization voltage line VIL2, and the sixth transistor T6. The seventh transistor T7 may be turned on in response to a second scan signal GB received through the second scan line SL2, and may transmit the second initialization voltage Vaint from the second initialization voltage line VIL2 to the first electrode of the light-emitting element LED, thereby initializing the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and retain a voltage corresponding to a difference in voltage between opposite ends of the first voltage line VDDL and the gate electrode of the first transistor T1, thereby retaining the voltage applied to the gate electrode of the first transistor T1.

Referring to FIG. 6C, in another embodiment, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC may be electrically connected to signal lines and voltage lines. The signal lines may include the gate line, such as the first scan line SL1, the second scan line SL2, the third scan line SL3, and the emission control line EML, and the data line DL. The voltage lines may include the first and second initialization voltage lines VL1 and VL2, a sustain voltage line VSL, and the first voltage line VDDL.

The first voltage line VDDL may transmit the first power voltage VDD to the first transistor T1. The first initialization voltage line VIL1 may transmit the first initialization voltage Vint for initializing the first transistor T1 to the pixel driving circuit portion PC. The second initialization voltage line VIL2 may transmit the second initialization voltage Vaint for initializing the first electrode of the light-emitting element LED to the pixel driving circuit portion PC. The sustain voltage line VSL may provide a sustain voltage VSUS to a second node N2, for example, the second electrode CE2 of the storage capacitor Cst, in an initialization section and a data write section.

The first transistor T1 may be electrically connected to the first voltage line VDDL via the fifth transistor T5 and the eighth transistor T8, and to the light-emitting element LED via the sixth transistor T6. The first transistor T1, which serves as a driving transistor, may receive the data signal Dm based on the switching operation of the second transistor T2, and supply a driving current to the light-emitting element LED.

The second transistor T2 may be electrically connected to the first scan line SL1 and the data line DL, and to the first voltage line VDDL via the fifth transistor T5 and the eighth transistor T8. The second transistor T2 may be turned on in response to the first scan signal GW received through the first scan line SL1 to perform a switching operation of transmitting the data signal Dm received through the data line DL to the first node N1.

The third transistor T3 may be electrically connected to the first scan line SL1, and to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 may be electrically connected to the third scan line SL3 and the first initialization voltage line VIL1, and may be turned on in response to the third scan signal GI received through the third scan line SL3 to transmit the first initialization voltage Vint received through the first initialization voltage line VIL1 to the gate electrode of the first transistor T1, thereby initializing the voltage of the gate electrode of the first transistor T1. The third scan signal GI may correspond to a first scan signal of another pixel driving circuit portion arranged in the previous row of the corresponding pixel driving circuit portion PC.

The fifth transistor T5, the sixth transistor T6, and the eighth transistor T8 may be electrically connected to the emission control line EML, and may be simultaneously turned on in response to the emission control signal EM received through the emission control line EML to form a current path through which a driving current flows in a direction from the first voltage line VDDL to the light-emitting element LED.

The seventh transistor T7, as a second initialization transistor, may be electrically connected to the second scan line SL2, the second initialization voltage line VIL2, and the sixth transistor T6. The seventh transistor T7 may be turned on in response to the second scan signal GB received through the second scan line SL2, and may transmit the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2, and may transmit the sustain voltage VSUS to the second node N2, for example, the second electrode CE2 of the storage capacitor Cst, in the initialization section and the data write section.

The eighth transistor T8 and the ninth transistor T9 may each be electrically connected to the second node N2, for example, the second electrode CE2 of the storage capacitor Cst. In some embodiments, in the initialization section and the data write section, the eighth transistor T8 may be turned off and the ninth transistor T9 may be turned on, and in a light-emitting section, the eighth transistor T8 may be turned on and the ninth transistor T9 may be turned off. In the initialization section and the data write section, as the sustain voltage VSUS is transmitted to the second node N2, uniformity of illumination (e.g., long range uniformity (LRU)) of a display apparatus according to voltage drop of the first voltage line VDDL may be improved.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting element LED. While the seventh transistor T7 and the ninth transistor T9 are turned on, the auxiliary capacitor Ca may store and retain a voltage corresponding to a difference in voltage between the first electrode of the light-emitting element LED and the sustain voltage line VSL, thereby effectively preventing an increase of black luminance when the sixth transistor T6 is turned off.

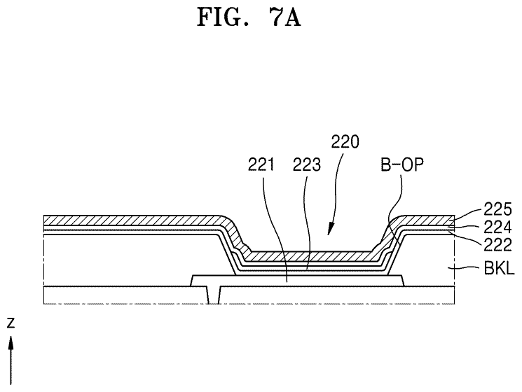

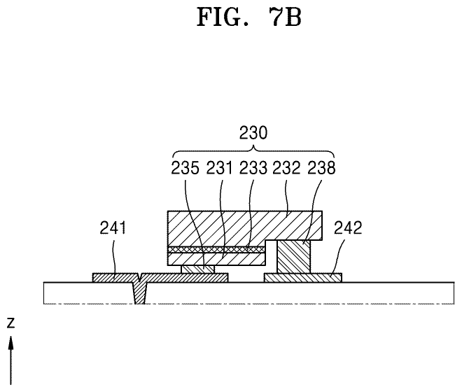

FIG. 7A is a schematic cross-sectional view of a light-emitting element of a display apparatus according to an embodiment of the present disclosure.

Referring to FIG. 7A, a light-emitting element according to an embodiment of the present disclosure may include an organic light-emitting diode 220 including an organic material. The organic light-emitting diode 220 may include a first electrode 221 disposed on an insulating layer, a second electrode 225 facing the first electrode 221, and an emission layer 223 between the first electrode 221 and the second electrode 225. A first functional layer 222 is arranged between the first electrode 221 and the emission layer 223, and a second functional layer 224 may be arranged between the emission layer 223 and the second electrode 225.

The edges of the first electrode 221 may be covered by a bank layer BKL that includes an insulating material. The bank layer BKL may define an opening B-OP that overlaps or exposes the central part of the first electrode 221.

The first electrode 221 may include a conductive oxide, such indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the first electrode 221 may further include a layer including or formed of ITO, IZO, ZnO, AZO, or In₂O₃ above/under the reflective layer described above.

The emission layer 223 may include a polymer or low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. In an embodiment, for example, the second electrode 225 may include a (semi-)transparent layer including Ag, Mg, Al, Pt, Pd, Au, Ni, Nd, Ir, Cr, lithium (Li), calcium (Ca), or an alloy thereof, etc. Alternatively, the second electrode 225 may further include a layer, such as a layer including ITO, IZO, ZnO, AZO, or In₂O₃, on the (semi-)transparent layer including the material described above.

FIG. 7B is a schematic cross-sectional view of a light-emitting element of a display apparatus according to an embodiment of the present disclosure.

Referring to FIG. 7B, a light-emitting element according to an embodiment of the present disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 arranged on the same layer.

In some embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, and 0≤(x+y)≤1), for example, GaN, AlN, AlGaN, InGaN, InN, InAlGaN, AlInN, etc., and may be doped with a p-type dopant, such as Mg, Zn, Ca, Sr, Ba, etc.

The second semiconductor layer 232 may include, for example, an n-type semiconductor layer. The n-type semiconductor layer may be selected from semiconductor materials having a composition formula of InₓAl_{y}Ga_{1-x-y}N (0≤x≤1, 0≤y≤1, and 0≤(x+y)≤1), for example, GaN, AlN, AlGaN, InGaN, InN, InAlGaN, AlInN, etc., and may be doped with an n-type dopant, such as Si, Ge, Sn, etc.

The intermediate layer 233 is a region where electrons and holes recombine, and as electrons and holes recombine, the electrons and holes transition to a lower energy level and may generate light having a corresponding wavelength. The intermediate layer 233 may include a semiconductor material having a composition formula of, for example, InₓAl_{y}Ga_{1-x-y}N (0≤x≤1, 0≤y≤1, and 0≤(x+y)≤1), and may be formed in a single quantum well structure or a multi-quantum well (MQW) structure. Furthermore, the intermediate layer 233 may have a quantum wire structure or a quantum dot structure.

FIG. 7B illustrates an embodiment where the first semiconductor layer 231 includes a p-type semiconductor layer, and that the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

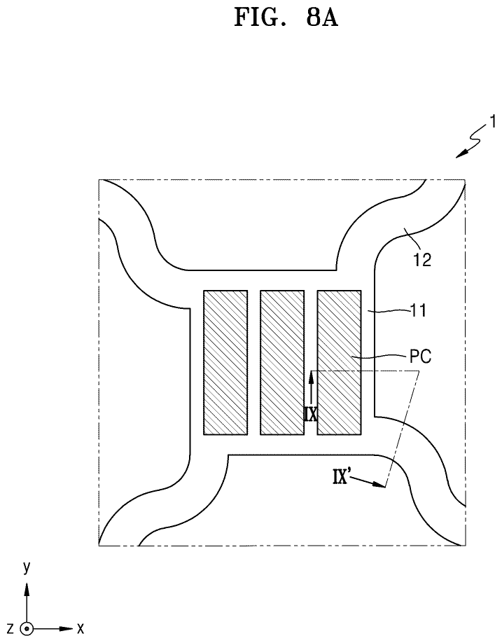

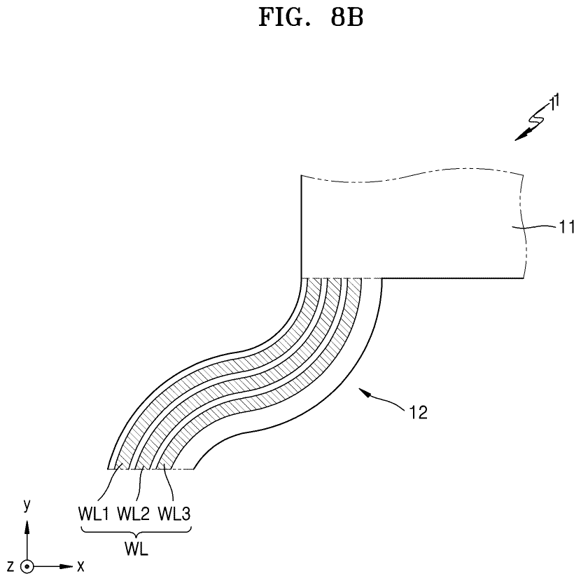

FIG. 8A is an enlarged plan view of the first island portion 11 of the display apparatus 1 according to an embodiment of the present disclosure. FIG. 8B is a plan view showing a layout of the wires WL on the first bridge portion 12 of the display apparatus 1 according to an embodiment of the present disclosure.

In detail, FIG. 8B is a plan view of the display apparatus 1 by enlarging a portion of FIG. 8A.

Referring to FIG. 8A, in an embodiment, each of the first island portions 11 arranged in the display area DA may include the light-emitting element and the pixel driving circuit portion PC electrically connected thereto. The pixel driving circuit portion PC may include, as described above, transistors and at least one capacitor. FIG. 8A illustrates an embodiment where three pixel driving circuit portions PC are arranged in the first island portion 11, but the disclosure is not limited thereto. In another embodiment, the numbers of the pixel driving circuit portions PC and light-emitting elements arranged in the first island portion 11 may be one, two, four, or more.

Referring to FIG. 8B, in an embodiment, each of the first bridge portions 12 may include the wires WL electrically connected to the pixel driving circuit portions PC arranged in each of the first island portions 11 adjacent thereto. The wires WL may be, as described above, a signal line (e.g., a gate line, a data line, etc.) for providing electrical signals or a voltage line (e.g., a driving voltage line, an initialization voltage line, etc.) for providing voltage to the transistors included in the pixel driving circuit portions PC of the first island portion 11. FIG. 8B illustrates an embodiment where the wires WL, for example, first to third wires WL1, WL2, and WL3 are arranged on the first bridge portion 12, but the disclosure is not limited thereto. In another embodiment, a single wire WL may be arranged on the first bridge portion 12.

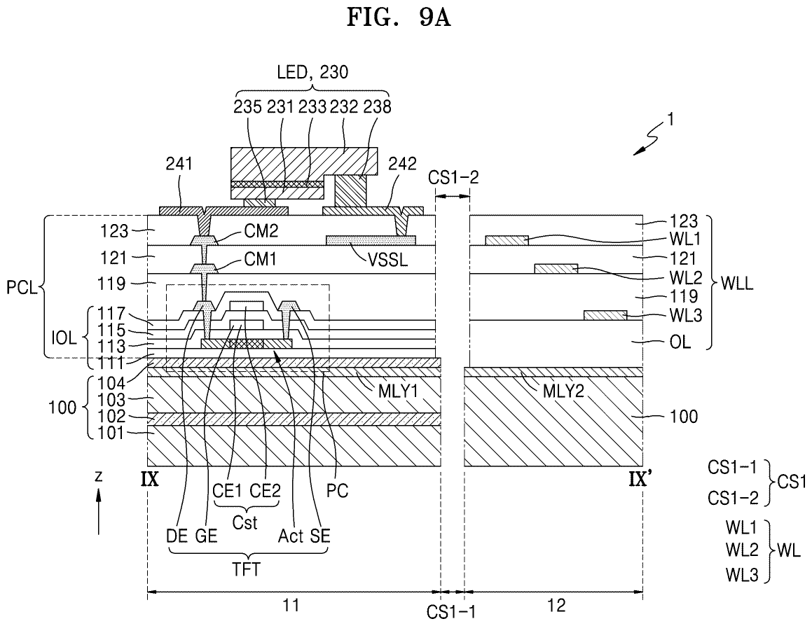

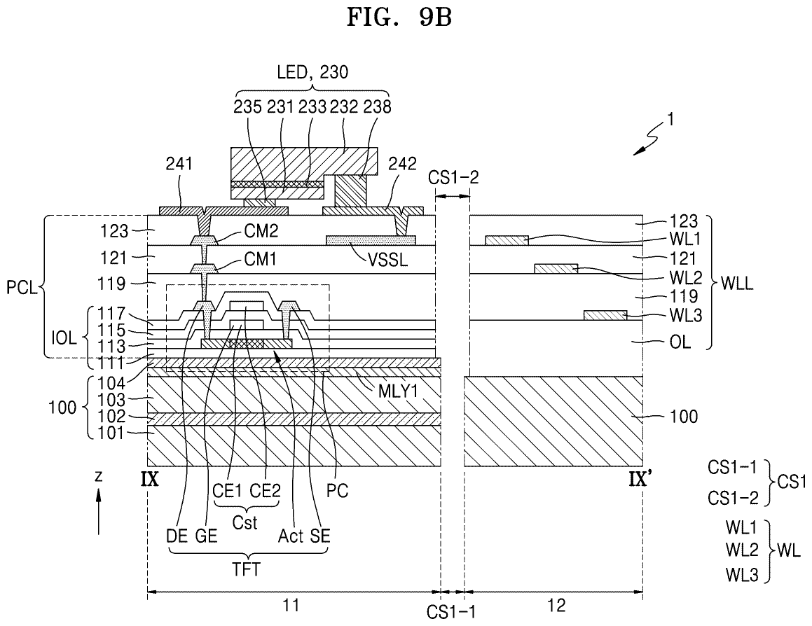

FIGS. 9A and 9B are schematic cross-sectional views of the display apparatus 1 according to an embodiment of the present disclosure.

In detail, FIGS. 9A and 9B are cross-sectional view of the display apparatus 1 taken along line IX-IX′ of FIG. 8A.

Referring to FIGS. 9A and 9B, an embodiment of the display apparatus 1 may include the substrate 100, a first mask layer MLY1, a pixel circuit layer PCL, a wiring layer WLL, and the light-emitting element LED.

A portion of the substrate 100 that is overlapped with (corresponding to or included in) the first island portions 11 may include a first base layer 101, a first barrier layer 102, a second base layer 103, and a second barrier layer 104. The first barrier layer 102 may be disposed on the first base layer 101, the second base layer 103 may be disposed on the first barrier layer 102, and the second barrier layer 104 may be disposed on the second base layer 103.

The first base layer 101 and the second base layer 103 may include a same material as each other. In an embodiment, for example, the first base layer 101 and the second base layer 103 may each include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc. The first barrier layer 102 and the second barrier layer 104 may include a same material as each other. In an embodiment, for example, the first barrier layer 102 and the second barrier layer 104 may each include an inorganic insulating material, such as silicon oxide, nitride silicon, or silicon oxynitride.

A portion of the substrate 100 that is overlapped with the first bridge portions 12 may include the same material as the first base layer 101 and/or the second base layer 103. In an embodiment, for example, the portion of the substrate 100 that is overlapped with the first bridge portions 12 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

In an embodiment having the structure described above, the substrate 100 may include a base layer that is overlapped with each of the first island portions 11 and the first bridge portions 12. FIGS. 9A and 9B illustrate an embodiment where the portion of the substrate 100 that is overlapped with the first bridge portions 12 has a structure of a single base layer, but this is an example and the portion of the substrate 100 that is overlapped with the first bridge portions 12 may have a stack structure of two base layers. Furthermore, the substrate 100 may further include a barrier layer (e.g., the first barrier layer 102 and/or the second barrier layer 104) that is overlapped with the first island portions 11. The barrier layer may be spaced apart from the first bridge portions 12, that is, not included in the portion of the substrate 100 that is overlapped with the first bridge portions 12.

The first mask layer MLY1 may be disposed on a base layer (e.g., the second base layer 103) to be overlapped with the first island portions 11. A barrier layer (e.g., the second barrier layer 104) may be disposed on the first mask layer MLY1. In other words, the first mask layer MLY1 may be arranged between the second base layer 103 and the second barrier layer 104. In an embodiment, for example, the first mask layer MLY1 may include at least one material selected from a transparent conducting oxide (TCO), metal, and silicon oxide. The etching selectivity of the first base layer 101 and the second base layer 103 with respect to the first mask layer MLY1 may exceed 1. In an embodiment, for example, the etching selectivity of the first base layer 101 and the second base layer 103 with respect to the first mask layer MLY1 may be 40 or greater. However, this is an example and the etching selectivity of the first base layer 101 and the second base layer 103 with respect to the first mask layer MLY1 is not limited thereto.

The pixel circuit layer PCL may be disposed on the first mask layer MLY1. The pixel circuit layer PCL may include an inorganic insulating layer IOL and the pixel driving circuit portion PC. In an embodiment, for example, the inorganic insulating layer IOL may include the buffer layer 111, a gate insulating layer 113, a first interlayer insulating layer 115, and a second interlayer insulating layer 117. In an embodiment, for example, the pixel driving circuit portion PC may include a thin film transistor TFT and the storage capacitor Cst.

The buffer layer 111 may be disposed on the substrate 100, and the pixel driving circuit portion PC may be disposed on the buffer layer 111. The buffer layer 111 may include an inorganic insulating material, such as silicon oxide, nitride silicon, or silicon oxynitride.

The thin film transistor TFT may include a semiconductor layer Act, a gate electrode GE, a source electrode SE, and a drain electrode DE. FIGS. 9A and 9B illustrate an embodiment where the gate electrode GE is of a top gate type disposed on the semiconductor layer Act with the gate insulating layer 113 therebetween, but according to another embodiment, the thin film transistor TFT may be of a bottom gate type.

The semiconductor layer Act may include polysilicon. Alternatively, the semiconductor layer Act may include amorphous silicon, oxide semiconductor, organic semiconductor, etc. The gate electrode GE may include a low-resistance metal material. The gate electrode GE may include a conductive material including molybdenum (Mo), Al, copper (Cu), titanium (Ti), etc., and may be formed in a multilayer or single layer including at least one selected from the material described above.

The gate insulating layer 113 between the semiconductor layer Act and the gate electrode GE may include an inorganic insulating material, such as silicon oxide, nitrogen oxide, silicon oxynitride, aluminum oxide, or titanium oxide. The gate insulating layer 113 may be a single layer or multilayer including the material described above.

The source electrode SE and the drain electrode DE may be disposed on the same layer, for example, the second interlayer insulating layer 117, and may include the same material. The source electrode SE and the drain electrode DE may include a conductive material, and may be formed in a multilayer or single layer. The second interlayer insulating layer 117 may include an inorganic insulating material, such as silicon oxide, nitrogen oxide, silicon oxynitride, aluminum oxide, or titanium oxide, and may be a single layer or multilayer including at least one selected from the materials described above.

The storage capacitor Cst may include a first electrode CE1 and a second electrode CE2 overlapping each other with the first interlayer insulating layer 115 therebetween. The storage capacitor Cst may overlap the thin film transistor TFT in the z direction. FIGS. 9A and 9B illustrates an embodiment where the gate electrode GE of the thin film transistor TFT is the first electrode CE1 of the storage capacitor Cst. In another embodiment, the storage capacitor Cst may not be overlapped with the thin film transistor TFT. The storage capacitor Cst may be covered by a second interlayer insulating layer 117. The second electrode CE2 of the storage capacitor Cst may include a conductive material, and may be formed in a multilayer or single layer. The first interlayer insulating layer 115 may be arranged between the gate insulating layer 113 and the second interlayer insulating layer 117. The first interlayer insulating layer 115 may include an inorganic insulating material, such as silicon oxide, nitrogen oxide, silicon oxynitride, aluminum oxide, or titanium oxide, and may be formed in a single layer or multilayer including at least one selected from the materials described above.

In an embodiment, for example, the pixel circuit layer PCL may include a first organic insulating layer 119, a second organic insulating layer 121, and a third organic insulating layer 123. The first organic insulating layer 119 may be disposed on the second interlayer insulating layer 117, and the second organic insulating layer 121 may be disposed on the first organic insulating layer 119. The first organic insulating layer 119 and the second organic insulating layer 121 may each include an organic insulating material such as polyimide.

A second voltage line VSSL may be disposed on the second organic insulating layer 121, and the third organic insulating layer 123 may be disposed on the second organic insulating layer 121 and the second voltage line VSSL. The third organic insulating layer 123 may include an organic insulating material such as polyimide. The second voltage line VSSL may include a conductive material, and may be formed in a multilayer or single layer.

A first electrode pad 241 and a second electrode pad 242 may be disposed on the third organic insulating layer 123. The first electrode pad 241 may be electrically connected to the thin film transistor TFT through a first connection electrode CM1 between the first organic insulating layer 119 and the second organic insulating layer 121 and a second connection electrode CM2 between the second organic insulating layer 121 and the third organic insulating layer 123.

The light-emitting element LED may be arranged on the pixel circuit layer PCL. The light-emitting element LED may include the organic light-emitting diode 220 (see FIG. 7A) (LED) described with reference to FIG. 7A and/or the inorganic light-emitting diode 230 descried with reference to FIG. 7B. In the following description, embodiments where the light-emitting element LED includes the inorganic light-emitting diode 230 will be mainly described for convenience of description.

The wiring layer WLL may be disposed on the substrate 100 to be overlapped with the first bridge portions 12. As no barrier layer is disposed on the first bridge portions 12, the wiring layer WLL may be disposed on the base layer overlapping the first bridge portions 12. The wiring layer WLL may include a first insulating layer OL, the first organic insulating layer 119, the second organic insulating layer 121, the third organic insulating layer 123, and the wire WL.

The inorganic insulating layer IOL is not disposed on the portion of the substrate 100 that is overlapped with the first bridge portions 12, and the first insulating layer OL, the first organic insulating layer 119, and the second organic insulating layer 121 may be disposed thereon. The first insulating layer OL may include an organic insulating material such as polyimide. In an embodiment, the first insulating layer OL may have a thickness corresponding to the inorganic insulating layer IOL. In some embodiments, the first insulating layer OL may be omitted.

The wires WL, for example, the first to third wires WL1, WL2, and WL3, may be disposed in (or directly on) different layers, respectively, and electrically connected to a same pixel driving circuit portion PC. In an embodiment, for example, the first wire WL1 may be arranged between the second organic insulating layer 121 and the third organic insulating layer 123, the second wire WL2 may be arranged between the first organic insulating layer 119 and the second organic insulating layer 121, and the third wire WL3 may be arranged between the first insulating layer OL and the first organic insulating layer 119. However, the disclosure is not limited thereto, and in another embodiment, at least some of the first to third wires WL1, WL2, and WL3 may be disposed in (or directly on) a same layer as each other. In an embodiment having the structure described above, the pixel circuit layer PCL and the wiring layer WLL may be disposed in (or directly on) a same layer as each other.

The first opening portion CS1 arranged between the first island portions 11 and the first bridge portions 12 in a cross-sectional view, may include a first first opening portion (hereinafter, will be referred to as “first-1 opening portion”) CS1-1 and a second first opening portion (hereinafter, will be referred to as “first-2 opening portion”) CS1-2 arranged to be overlapped with each other. The first-1 opening portion CS1-1 may penetrate (or be defined through) the substrate 100 and the first mask layer MLY1, and the first-2 opening portion CS1-2 may penetrate (or be defined through) the pixel circuit layer PCL and the wiring layer WLL. In a cross-sectional view, the portion of the substrate 100 that is overlapped with the first island portions 11 and the portion of the substrate 100 that is overlapped with the first bridge portions 12 may be separated from each other with the first-1 opening portion CS1-1 therebetween. In a cross-sectional view, the pixel circuit layer PCL and the wiring layer WLL may be separated from each other with the first-2 opening portion CS1-2 therebetween.

The width of the first mask layer MLY1 may be the same as the width of the portion of the substrate 100 that is overlapped with the first island portions 11. The width of the first mask layer MLY1 may be greater than the width of the pixel circuit layer PCL. The width of the portion of the substrate 100 that is overlapped with the first bridge portions 12 may be greater than the width of the wiring layer WLL. In an embodiment having the structure described above, in a cross-sectional view, the width of the first-1 opening portion CS1-1 may be less than the width of the first-2 opening portion CS1-2.

In an embodiment, as illustrated in FIG. 9A, the display apparatus 1 may further include a second mask layer MLY2. The second mask layer MLY2 may be disposed on the portion of the substrate 100 that is overlapped with the first bridge portions 12. As no barrier layer is disposed on the portion of the substrate 100 that is overlapped with the first bridge portions 12, the second mask layer MLY2 may be disposed on the base layer to be overlapped with the first bridge portions 12. The width of the second mask layer MLY2 may be the same as the width of the portion of the substrate 100 that is overlapped with the first bridge portions 12. The width of the second mask layer MLY2 may be greater than the width of the wiring layer WLL.

At this time, the first mask layer MLY1 and the second mask layer MLY2 may be disposed in (or directly on) a same layer as each other and may include a same material as each other. The width of the second mask layer MLY2 may be the same as the width of the portion of the substrate 100 that is overlapped with the first bridge portions 12. The width of the second mask layer MLY2 may be greater than the width of the wiring layer WLL. In an embodiment, for example, the second mask layer MLY2 may include at least one material selected from TCO, metal, and silicon oxide. However, this is an example and the material included in the second mask layer MLY2 is not limited thereto.

In an embodiment, as illustrated in FIG. 9B, the display apparatus 1 may not include the second mask layer MLY2. In an embodiment having the structure described above, the wiring layer WLL may be disposed on the portion of the substrate 100 that is overlapped with the first bridge portions 12. In such an embodiment, the first insulating layer OL may be disposed directly on the portion of the substrate 100 that is overlapped with the first bridge portions 12.

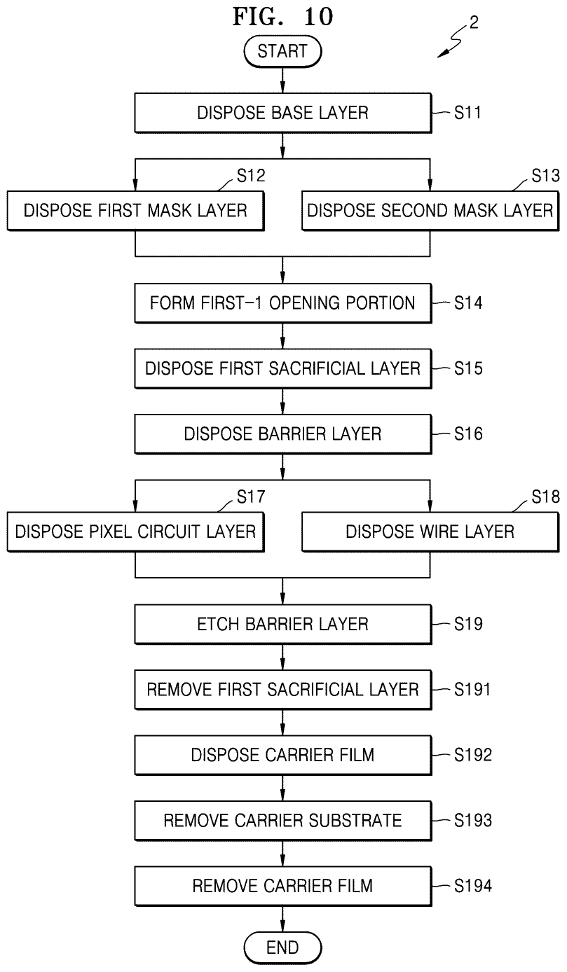

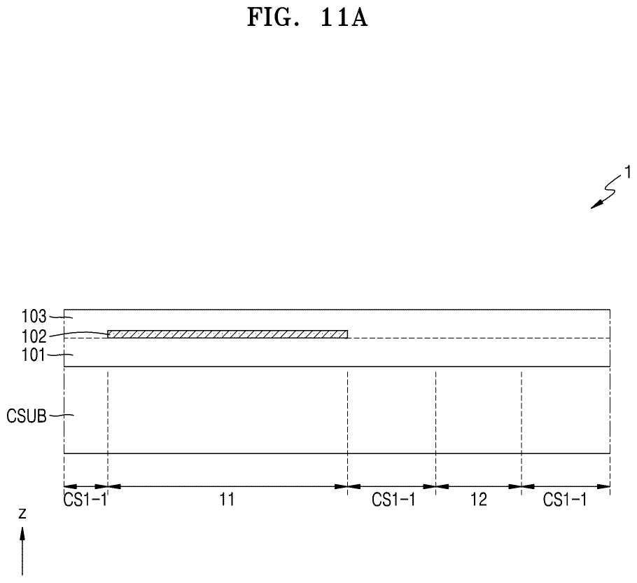

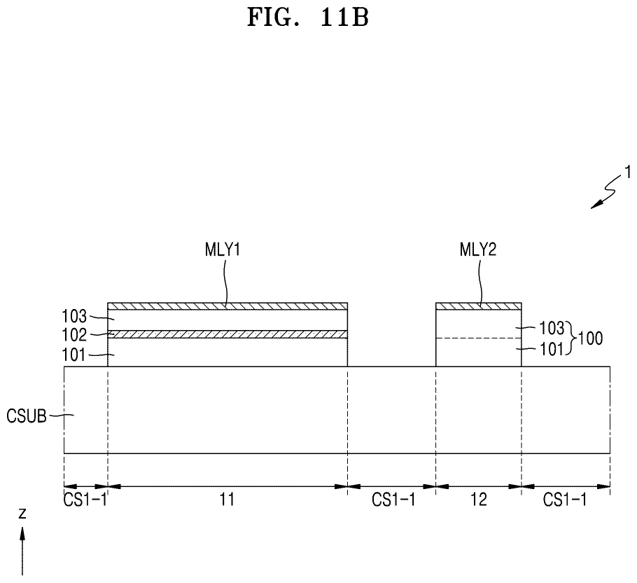

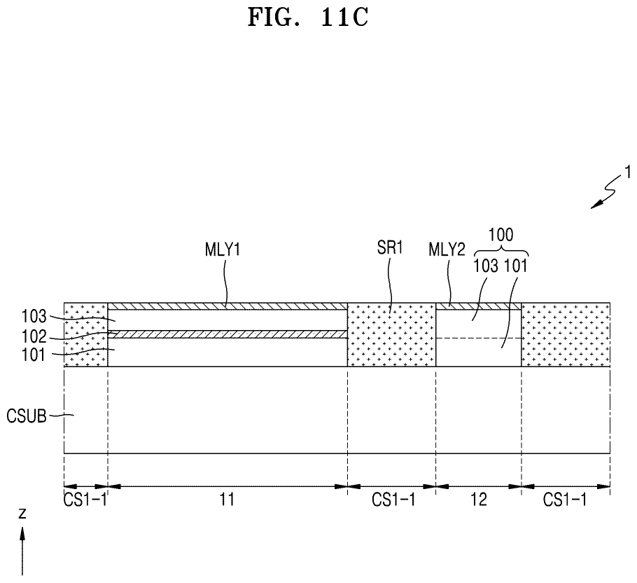

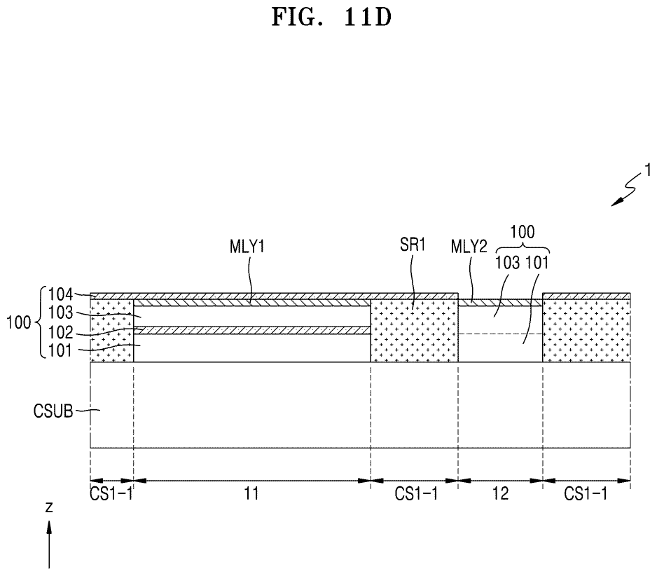

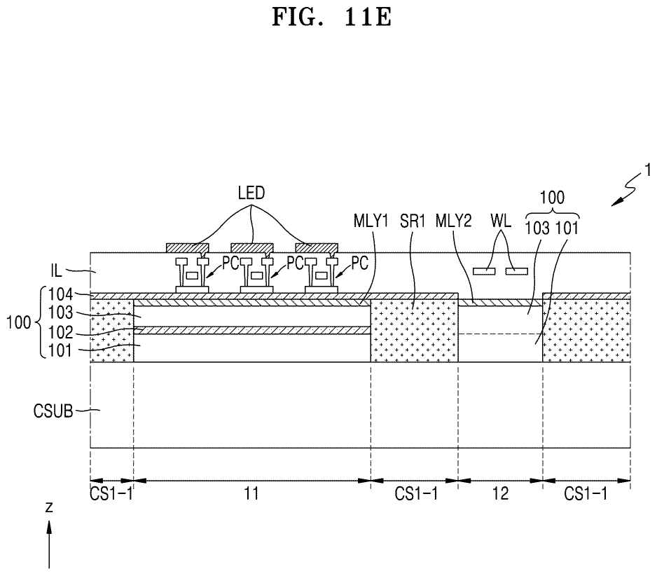

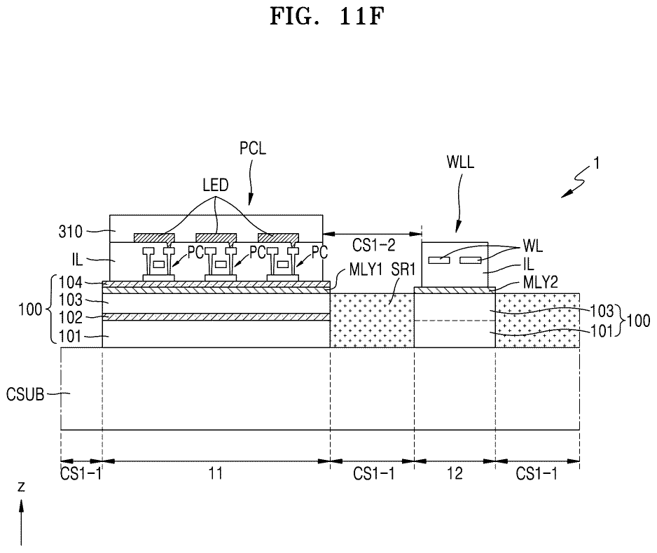

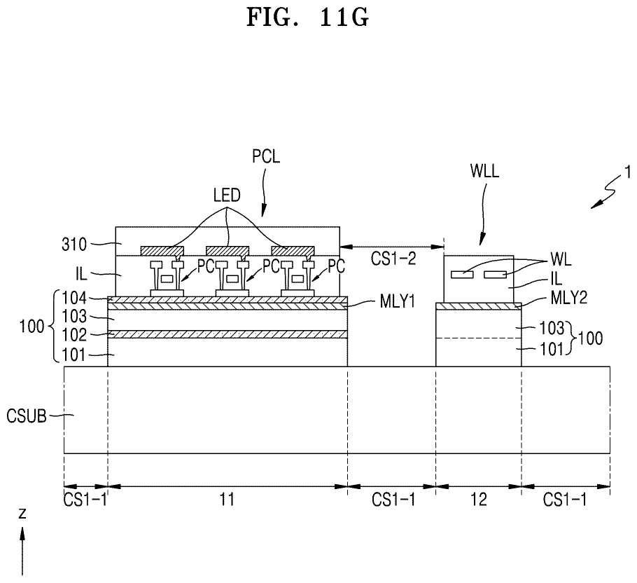

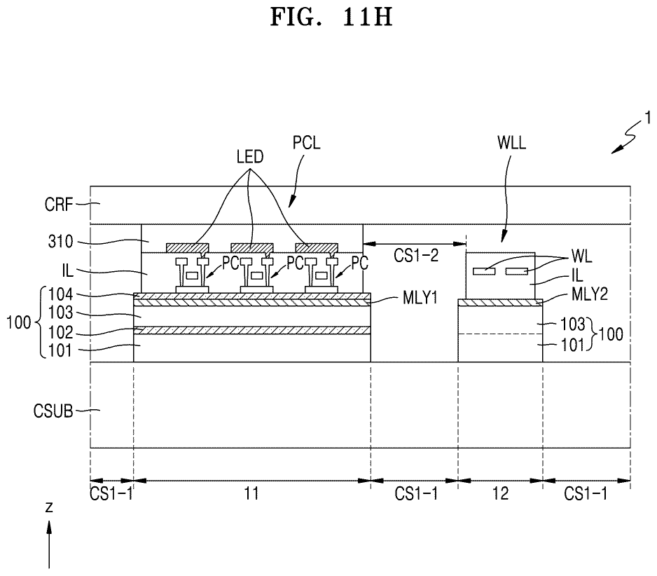

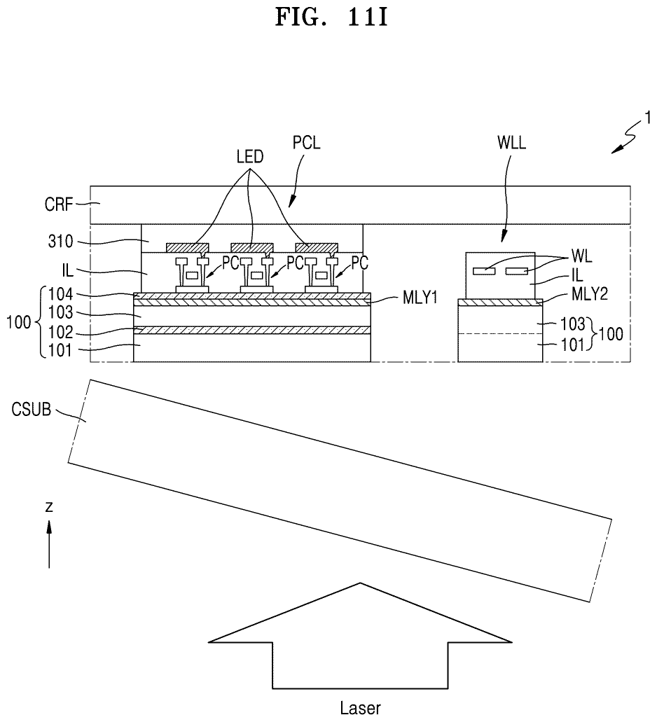

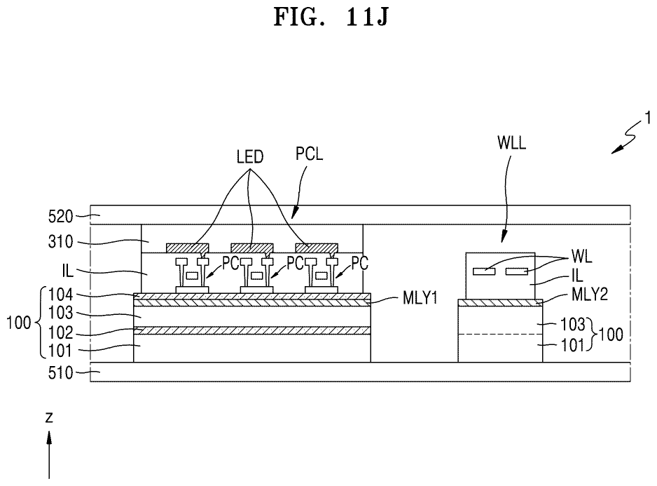

FIG. 10 is a schematic flowchart of a method 2 of manufacturing a display apparatus, according to an embodiment of the present disclosure. FIGS. 11A to 11J are schematic cross-sectional views of the display apparatus 1 according to an embodiment of the present disclosure.

Referring to FIGS. 10 to 11J, an embodiment of the method 2 of manufacturing the display apparatus 1 described with reference to FIGS. 9A and 9B will be described in detail.

In FIGS. 10 to 11J, the same reference numerals as those in FIGS. 9A and 9B denote the same elements, and thus any repetitive detailed descriptions thereof will be omitted or simplified.

First, referring to FIGS. 10 and 11A, an embodiment of the method 2 of manufacturing a display apparatus may include disposing a base layer on a carrier substrate CSUB (S11). The first base layer 101 may be disposed on the carrier substrate CSUB. The carrier substrate CSUB may function to support the first base layer 101 in a processing process and may be provided as glass. The first barrier layer 102 may be disposed on first base layer 101. The second base layer 103 may be disposed on the first base layer 101 to cover the first barrier layer 102.

Referring to FIGS. 10 and 11B, an embodiment of the method 2 of manufacturing a display apparatus may further include disposing the first mask layer MLY1 on the base layer (S12), and disposing the second mask layer MLY2 on the base layer (S13).

In the disposing of the first mask layer MLY1 (S12), the first mask layer MLY1 may be overlapped with the first barrier layer 102. In other words, the first barrier layer 102 may be disposed on the first base layer 101, the second base layer 103 may be disposed on the first barrier layer 102, and the first mask layer MLY1 may be arranged on the second base layer 103.

In the disposing of the second mask layer MLY2 (S13), the second mask layer MLY2 may be separated (or spaced apart) from the first mask layer MLY1 in a cross-sectional view. The second base layer 103 may be disposed on the first base layer 101, and the second mask layer MLY2 may be disposed on the second base layer 103. The disposing of the first mask layer MLY1 (S12) and the disposing of the second mask layer MLY2 (S13) may be simultaneously performed.

Furthermore, an embodiment of the method 2 of manufacturing a display apparatus may further include forming the first-1 opening portion CS1-1 in the base layer (S14). As portions of the base layer, which are not overlapped with the first mask layer MLY1 and the second mask layer MLY2, are etched, the first-1 opening portion CS1-1 may be formed in the base layer. The first-1 opening portion CS1-1 may be formed through the first base layer 101 and the second base layer 103.

The etching of the base layer may be performed above the display apparatus 1 by a dry etching method using an etching gas or a wet etching method using an etching solution. In the etching process of the base layer, the first mask layer MLY1 and the second mask layer MLY2 may be hardly etched. Portions of the base layer, which are overlapped with the first mask layer MLY1 and the second mask layer MLY2, may not be etched. Portions of the base layer, which are separated from the first mask layer MLY1 and the second mask layer MLY2, may be removed. The first base layer 101 and the second base layer 103, which are overlapped with the second mask layer MLY2, may form the substrate 100 of the first bridge portions 12.

Referring to FIGS. 10 and 11C, an embodiment of the method 2 of manufacturing a display apparatus may further include arranging (or providing) a first sacrificial layer SR1 within the first-1 opening portion CS1-1 (S15). The first sacrificial layer SR1 may be accommodated in the first-1 opening portion CS1-1. The first sacrificial layer SR1 may be supported by the carrier substrate CSUB. The first sacrificial layer SR1 may be surrounded by the first base layer 101, the first barrier layer 102, the second base layer 103, the first mask layer MLY1, and the second mask layer MLY2. The etching selectivity of the first sacrificial layer SR1 to the first base layer 101 and the second base layer 103 may exceed 1. In an embodiment, for example, the first sacrificial layer SR1 may include at least one selected from metal ink, metal paste, or liquid silicon.

Referring to FIGS. 10 and 11D, an embodiment of the method 2 of manufacturing a display apparatus may further include disposing a barrier layer (e.g., the second barrier layer 104) on the first mask layer MLY1 (S16). The second barrier layer 104 may cover the first mask layer MLY1 and the first sacrificial layer SR1. The second barrier layer 104 may not be overlapped with the second mask layer MLY2. The first base layer 101, the first barrier layer 102, the second base layer 103, and the second barrier layer 104, which are overlapped with first mask layer MLY1, may form the substrate 100 of the first island portions 11.

Referring to FIGS. 10, 11E, and 11F, an embodiment of the method 2 of manufacturing a display apparatus may further include disposing the pixel circuit layer PCL on the barrier layer (e.g., the second barrier layer 104) (S17), disposing the wiring layer WLL on the base layer (S18), and etching the barrier layer (S19).

As illustrated in FIG. 11E, the insulating layer IL, the pixel driving circuit portion PC, the wire WL, and the light-emitting element LED may be disposed on the second barrier layer 104 and the second mask layer MLY2.

As illustrated in FIG. 11F, a planarized film 310 may be disposed on the insulating layer IL to cover the light-emitting element LED. In an embodiment, for example, the planarized film 310 may include an inorganic insulating material and/or an organic insulating material. In an embodiment, for example, the planarized film 310 may include an inorganic material such as resin and/or urethane epoxy acrylate. In an embodiment, for example, the planarized film 310 may include a photosensitive material, for example, a material such as photoresist.

The insulating layer IL may be etched to form the first-2 opening portion CS1-2 that is overlapped with the first-1 opening portion CS1-1 and penetrates the insulating layer IL. The insulating layer IL may be etched by a well-known photolithography process. The etching of the insulating layer IL may be performed in the upper portion of the display apparatus 1 by the dry etching method using the etching gas or the wet etching method using the etching solution. As the insulating layer IL is etched, the pixel circuit layer PCL and the wiring layer WLL may be formed. In other words, the disposing of the pixel circuit layer PCL (S17), and the disposing of the wiring layer WLL (S18) may be simultaneously performed.

The pixel circuit layer PCL and the wiring layer WLL may be separated (or spaced apart) from each other with the first-2 opening portion CS1-2 therebetween, in a cross-sectional view. In such an embodiment, considering the tolerance in the etching process, the width of the first-2 opening portion CS1-2 may be greater than the width of the width of the first-1 opening portion CS1-1. In other words, the width of the first-1 opening portion CS1-1 may be less than the width of the first-2 opening portion CS1-2.

A portion of the second barrier layer 104, which is overlapped with the first-1 opening portion CS1-1, may be etched. The second barrier layer 104 may be etched by the well-known photolithography process. The etching of the second barrier layer 104 may be performed in the upper portion of the display apparatus 1 by the dry etching method using the etching gas or the wet etching method using the etching solution. As the second barrier layer 104 is etched, the first sacrificial layer SR1 may be exposed from the second barrier layer 104.

Referring to FIGS. 10, 11F, and 11G, an embodiment of the method 2 of manufacturing a display apparatus may further include removing the first sacrificial layer SR1 (S191).

The first sacrificial layer SR1 may be removed by an etching process. The etching of first sacrificial layer SR1 may be performed in the upper portion of the display apparatus 1 by the dry etching method using the etching gas or the wet etching method using the etching solution. In the etching process of the first sacrificial layer SR1, the first base layer 101 and the second base layer 103 may be hardly etched.

Referring to FIGS. 10 and 11H, an embodiment of the method 2 of manufacturing a display apparatus may further include disposing a carrier film CRF on the pixel circuit layer PCL (S192). The carrier film CRF may be attached to the planarized film 310 by an adhesive layer. The carrier film CRF, which is a protective film to facilitate handling in a subsequent process, may include a flexible plastic material, such as polyethylene terephthalate (PET), polyimide, etc.

Referring to FIGS. 10 and 11I, an embodiment of the method 2 of manufacturing a display apparatus may further include removing the carrier substrate CSUB (S193). The carrier substrate CSUB may be separated from the substrate 100 by a laser lift-off method of radiating a laser beam onto a lower portion of the carrier substrate CSUB. Alternatively, the carrier substrate CSUB may be separated from the substrate 100 by using the well-known physical or chemical method.

Referring to FIGS. 10, 11I, and 11J, an embodiment of the method 2 of manufacturing a display apparatus may further include removing the carrier film CRF (S194). At this time, a first encapsulation layer 510 may be attached to a lower surface of the substrate 100 by a lamination process. A second encapsulation layer 520 may be attached to an upper surface of the planarized film 310 by the lamination process. In other words, the substrate 100, the pixel circuit layer PCL, the light-emitting element LED, and the wiring layer WLL may be arranged between the first encapsulation layer 510 and the second encapsulation layer 520.

The first encapsulation layer 510 and the second encapsulation layer 520 may each be formed of or defined by a stretchable sheet. The first encapsulation layer 510 may be provided as an elastomer film, a polydimethylsiloxane (PDMS) film, and/or a silicon film. The second encapsulation layer 520 may be formed of or defined by a stretchable sheet. The second encapsulation layer 520 may include a same material as that of the first encapsulation layer 510. The second encapsulation layer 520 may be provided as an elastomer film, a PDMS film, and/or a silicon film.

In an embodiment, the etching of the substrate 100 (in detail, the first base layer 101 and the second base layer 103), and the etching of the pixel circuit layer PCL and the wiring layer WLL (in detail, the insulating layer IL), may not be simultaneously performed. The pixel circuit layer PCL and the wiring layer WLL may be etched after the substrate 100 is first etched.

In this process, the substrate 100, the pixel circuit layer PCL and the wiring layer WLL may not be exposed, at one time, to the etching process for a long time. Accordingly, due to the long etching process, a phenomenon that damage is given to the pixel driving circuit portion PC and the wire WL may be reduced. Furthermore, a phenomenon that, after the etching process is completed, a step occurs in the heights of the pixel circuit layer PCL and the wiring layer WLL may be reduced.

in another embodiment, the method 2 of manufacturing a display apparatus may further include removing the second mask layer MLY2 after the forming of the first-1 opening portion CS1-1 (S14). According to the above process, the second mask layer MLY2 may not be arranged in the first bridge portions 12, as illustrated in FIG. 9B. Accordingly, the elongation of the first bridge portions 12 may be improved.

In an embodiment, as illustrated in FIGS. 10 to 11I, the method 2 of manufacturing a display apparatus may not include the removing of the second mask layer MLY2. According to the above process, the second mask layer MLY2 may be arranged in the first bridge portions 12, as illustrated in FIG. 9A. In this process, as a manufacturing process is simplified, the manufacturing time and manufacturing costs of the display apparatus 1 may be reduced.

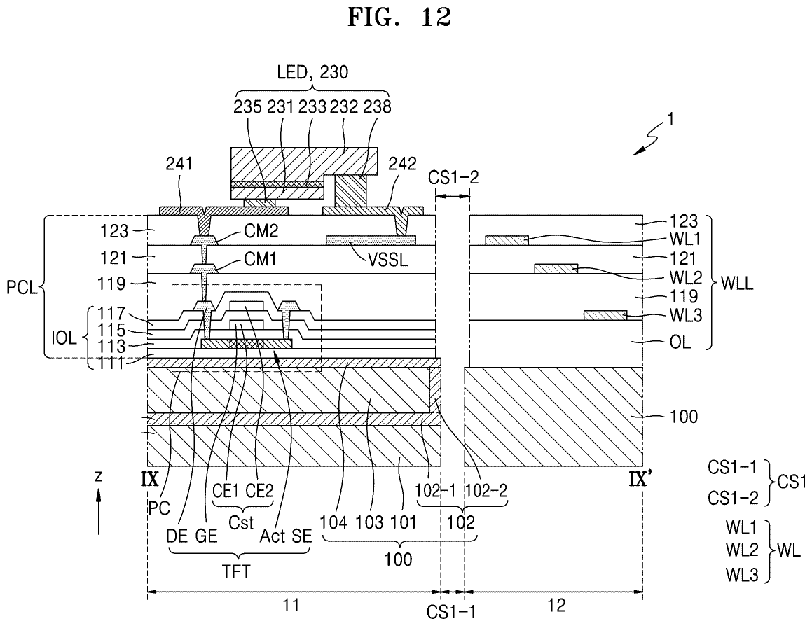

FIG. 12 is a schematic cross-sectional view of the display apparatus 1 according to an embodiment of the present disclosure.

In detail, FIG. 12 is a cross-sectional view of the display apparatus 1 taken along line IX-IX′ line of FIG. 8A.

Referring to FIG. 12, an embodiment of the display apparatus 1 may include the substrate 100, the pixel circuit layer PCL, the wiring layer WLL, and the light-emitting element LED.

The portion of the substrate 100 that is overlapped with the first island portions 11 may include the first base layer 101, the first barrier layer 102, the second base layer 103, and the second barrier layer 104. The first barrier layer 102 may be disposed on the first base layer 101, the second base layer 103 may be disposed on the first barrier layer 102, and the second barrier layer 104 may be disposed on the second base layer 103.

The first barrier layer 102 and the second barrier layer 104 may surround the second base layer 103. The second base layer 103 may be sealed by the first barrier layer 102 and the second barrier layer 104. The second base layer 103 may be accommodated in the first barrier layer 102. The lower surface and side surface of the second base layer 103 may be in contact with the first barrier layer 102, and the upper surface of the second base layer 103 may be in contact with the second barrier layer 104. The first barrier layer 102 may include a first first barrier portion (hereinafter, will be referred to as “first-1 barrier portion”) 102-1 and a second first barrier portion (hereinafter, will be referred to as “first-2 barrier portion”) 102-2.

The first-1 barrier portion 102-1 may have a flat layer shape. The first-1 barrier portion 102-1 may support the lower surface of the second base layer 103. The lower surface of the first-1 barrier portion 102-1 may be in contact with the first base layer 101, and the upper surface of the first-1 barrier portion 102-1 may be in contact with the second base layer 103.

The first-2 barrier portion 102-2 may extend from the first-1 barrier portion 102-1 toward the second barrier layer 104. The first-2 barrier portion 102-2 may extend from an edge of the first-1 barrier portion 102-1. The first-2 barrier portion 102-2 may surround the second base layer 103. The second base layer 103 may be accommodated in the first-1 barrier portion 102-1. The first-2 barrier portion 102-2 and the second barrier layer 104 may be in contact with each other. The upper surface of the first-2 barrier portion 102-2 may be connected to an edge of the second barrier layer 104.

The first base layer 101 and the second base layer 103 may include a same material as each other. In an embodiment, for example, the first base layer 101 and the second base layer 103 may each include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc. The first barrier layer 102 and the second barrier layer 104 may include a same material as each other. In an embodiment, for example, the first barrier layer 102 and the second barrier layer 104 may each include an inorganic insulating material, such as silicon oxide, nitride silicon, or silicon oxynitride.

The portion of the substrate 100 that is overlapped with the first bridge portions 12 may include a same material as the first base layer 101 and/or the second base layer 103. In an embodiment, for example, the portion of the substrate 100 that is overlapped with the first bridge portions 12 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

In such an embodiment having the structure described above, the substrate 100 may include a base layer that is overlapped with each of the first island portions 11 and the first bridge portions 12. FIG. 12 illustrates an embodiment where the portion of the substrate 100 that is overlapped with the first bridge portions 12 has a structure of a single base layer, this is an example and the portion of the substrate 100 that is overlapped with the first bridge portions 12 may have a stack structure of two base layers. Furthermore, the substrate 100 may further include a barrier layer (e.g., the first barrier layer 102 and/or the second barrier layer 104) that is overlapped with the first island portions 11. The barrier layer may be spaced apart from the first bridge portions 12.

The pixel circuit layer PCL may be disposed on the portion of the substrate 100 that is overlapped with the first island portions 11. The pixel circuit layer PCL may include the inorganic insulating layer IOL and the pixel driving circuit portion PC. In an embodiment, for example, the inorganic insulating layer IOL may include the buffer layer 111, the gate insulating layer 113, the first interlayer insulating layer 115, and the second interlayer insulating layer 117. In an embodiment, for example, the pixel driving circuit portion PC may include the thin film transistor TFT and the storage capacitor Cst.

The buffer layer 111 may be disposed on the portion of the substrate 100 that is overlapped with the first island portions 11, and the pixel driving circuit portion PC may be disposed on the buffer layer 111. The buffer layer 111 may include an inorganic insulating material, such as silicon oxide, nitride silicon, or silicon oxynitride.

The thin film transistor TFT may include the semiconductor layer Act, the gate electrode GE, the source electrode SE, and the drain electrode DE. FIG. 12 illustrates an embodiment where the gate electrode GE is of a top gate type disposed on the semiconductor layer Act with the gate insulating layer 113 therebetween, but according to another embodiment, the thin film transistor TFT may be of a bottom gate type.

The semiconductor layer Act may include polysilicon. Alternatively, the semiconductor layer Act may include amorphous silicon, oxide semiconductor, organic semiconductor, etc. The gate electrode GE may include a low-resistance metal material. The gate electrode GE may include a conductive material including Mo, Al, Cu, Ti, etc., and may be formed in a multilayer or single layer including at least one selected from the materials described above.

The gate insulating layer 113 between the semiconductor layer Act and the gate electrode GE may include an inorganic insulating material, such as silicon oxide, nitrogen oxide, silicon oxynitride, aluminum oxide, or titanium oxide. The gate insulating layer 113 may be a single layer or multilayer including at least one selected from the materials described above.

The source electrode SE and the drain electrode DE may be disposed on the same layer, for example, the second interlayer insulating layer 117, and may include the same material. The source electrode SE and the drain electrode DE may include a conductive material, and may be formed in a multilayer or single layer. The second interlayer insulating layer 117 may include an inorganic insulating material, such as silicon oxide, nitrogen oxide, silicon oxynitride, aluminum oxide, or titanium oxide, and may be a single layer or multilayer including at least one selected from the materials described above.

The storage capacitor Cst may include the first electrode CE1 and the second electrode CE2 overlapping each other with the first interlayer insulating layer 115 therebetween. The storage capacitor Cst may overlap the thin film transistor TFT in the z direction. FIG. 12 illustrates an embodiment where the gate electrode GE of the thin film transistor TFT is the first electrode CE1 of the storage capacitor Cst. In another embodiment, the storage capacitor Cst may not be overlapped with the thin film transistor TFT. The storage capacitor Cst may be covered by the second interlayer insulating layer 117. The second electrode CE2 of the storage capacitor Cst may include a conductive material, and may be formed in a multilayer or single layer. The first interlayer insulating layer 115 may be arranged between the gate insulating layer 113 and the second interlayer insulating layer 117. The first interlayer insulating layer 115 may include an inorganic insulating material, such as silicon oxide, nitrogen oxide, silicon oxynitride, aluminum oxide, or titanium oxide, and may be formed in a single layer or multilayer including at least one selected from the materials described above.

In an embodiment, for example, the pixel circuit layer PCL may include the first organic insulating layer 119, the second organic insulating layer 121, and the third organic insulating layer 123. The first organic insulating layer 119 may be disposed on the second interlayer insulating layer 117, and the second organic insulating layer 121 may be disposed on the first organic insulating layer 119. The first organic insulating layer 119 and the second organic insulating layer 121 may each include an organic insulating material such as polyimide.

The second voltage line VSSL may be disposed on the second organic insulating layer 121, and the third organic insulating layer 123 may be disposed on the second organic insulating layer 121 and the second voltage line VSSL. The third organic insulating layer 123 may include an organic insulating material such as polyimide. The second voltage line VSSL may include a conductive material, and may be formed in a multilayer or single layer.

The first electrode pad 241 and the second electrode pad 242 may be disposed on the third organic insulating layer 123. The first electrode pad 241 may be electrically connected to the thin film transistor TFT through the first connection electrode CM1 between the first organic insulating layer 119 and the second organic insulating layer 121 and the second connection electrode CM2 between the second organic insulating layer 121 and the third organic insulating layer 123.

The light-emitting element LED may be arranged on the pixel circuit layer PCL. The light-emitting element LED may include the organic light-emitting diode 220 (see FIG. 7A) (LED) described with reference to FIG. 7A and/or the inorganic light-emitting diode 230 descried with reference to FIG. 7B. In the following description, embodiments where the light-emitting element LED includes the inorganic light-emitting diode 230 will be mainly described for convenience of description.

The wiring layer WLL may be disposed on the substrate 100 to be overlapped with the first bridge portions 12. As no barrier layer is disposed on the first bridge portions 12, the wiring layer WLL may be disposed on the base layer overlapping the first bridge portions 12. The wiring layer WLL may include the first insulating layer OL, the first organic insulating layer 119, the second organic insulating layer 121, the third organic insulating layer 123, and the wire WL.

The inorganic insulating layer IOL is not disposed on the portion of the substrate 100 that is overlapped with the first bridge portions 12, and the first insulating layer OL, the first organic insulating layer 119, and the second organic insulating layer 121 may be disposed thereon. The first insulating layer OL may include an organic insulating material such as polyimide. In an embodiment, the first insulating layer OL may have a thickness corresponding to the inorganic insulating layer IOL. In some embodiments, the first insulating layer OL may be omitted.

The wires WL, for example, the first to third wires WL1, WL2, and WL3, may be disposed in (or directly on) different layers, respectively, and electrically connected to the same pixel driving circuit portion PC. In an embodiment, for example, the first wire WL1 may be arranged between the second organic insulating layer 121 and the third organic insulating layer 123, the second wire WL2 may be arranged between the first organic insulating layer 119 and the second organic insulating layer 121, and the third wire WL3 may be arranged between the first insulating layer OL and the first organic insulating layer 119. However, the disclosure is not limited thereto, and in another embodiment, at least some of the first to third wires WL1, WL2, and WL3 may be disposed in (or directly on) a same layer as each other. In an embodiment having the structure described above, the pixel circuit layer PCL and the wiring layer WLL may be disposed in (or directly on) a same layer as each other.

The first opening portion CS1 arranged between the first island portions 11 and the first bridge portions 12 in a cross-sectional view, may include the first-1 opening portion CS1-1 and the first-2 opening portion CS1-2 arranged to be overlapped with each other. The first-1 opening portion CS1-1 may penetrate (or be defined through) the substrate 100, and the first-2 opening portion CS1-2 may penetrate (or be defined through) the pixel circuit layer PCL and the wiring layer WLL. In a cross-sectional view, the portion of the substrate 100 that is overlapped with the first island portions 11 and the portion of the substrate 100 that is overlapped with the first bridge portions 12 may be separated from each other with the first-1 opening portion CS1-1 therebetween. In a cross-sectional view, the pixel circuit layer PCL and the wiring layer WLL may be separated from each other with the first-2 opening portion CS1-2 therebetween.

The width of the portion of the substrate 100 that is overlapped with the first island portions 11 may be greater than the width of the pixel circuit layer PCL. The width of each of the first barrier layer 102 and the second barrier layer 104 may be greater than the width of the pixel circuit layer PCL. Each of the width of the portion of the substrate 100 that is overlapped with the first bridge portions 12 may be greater than the width of the wiring layer WLL. In an embodiment having the structure described above, in a cross-sectional view, the width of the first-1 opening portion CS1-1 may be less than the width of the first-2 opening portion CS1-2.

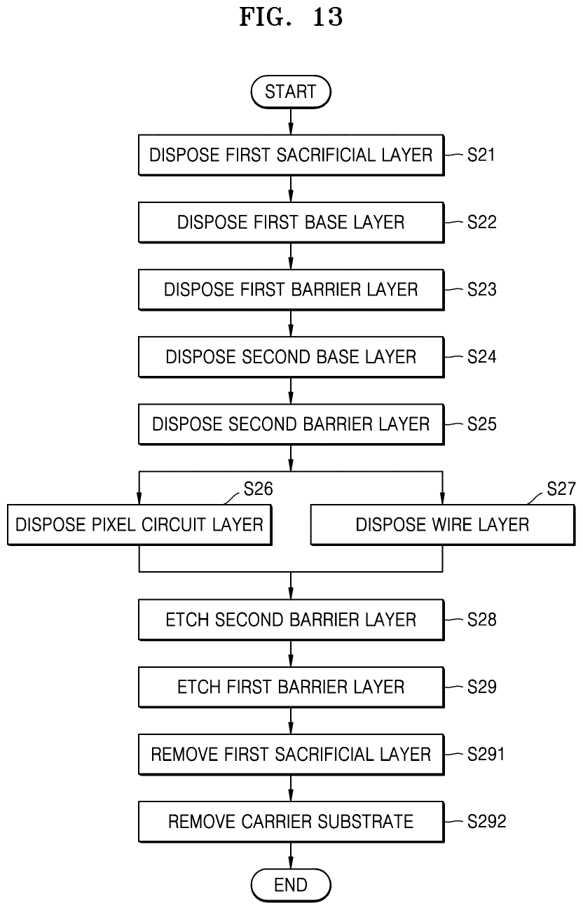

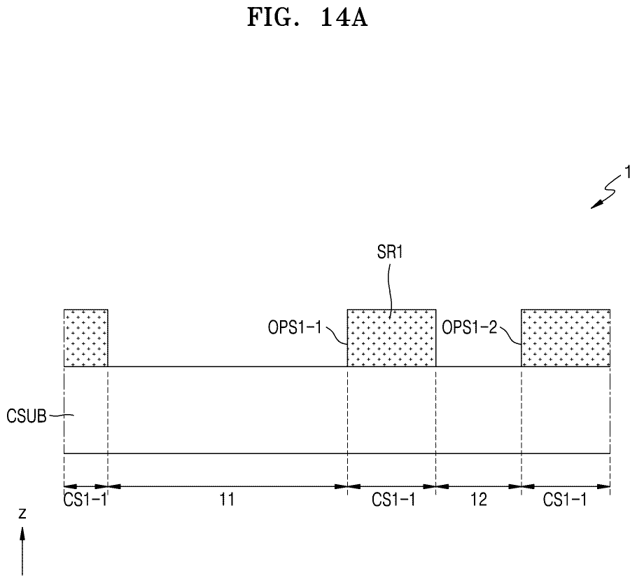

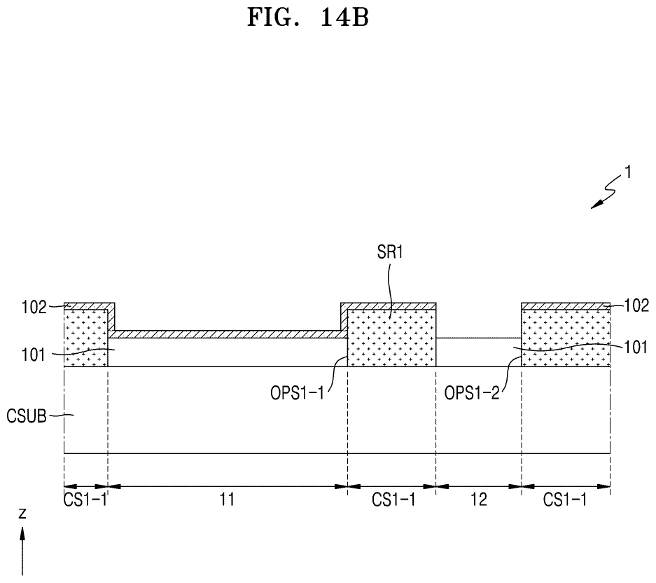

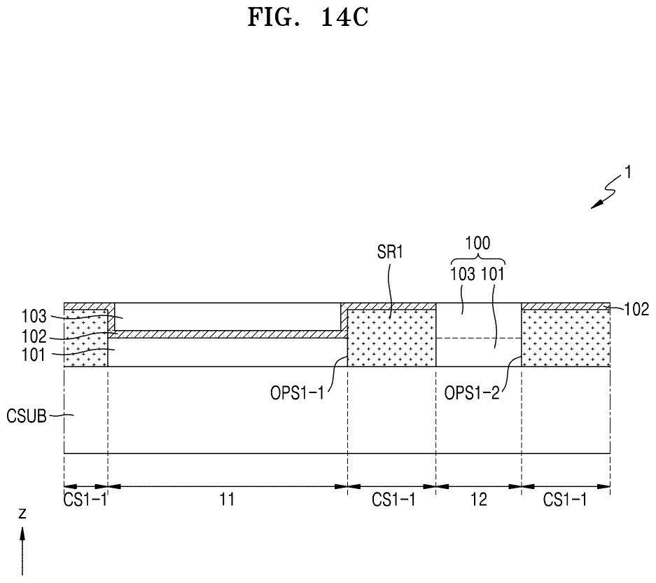

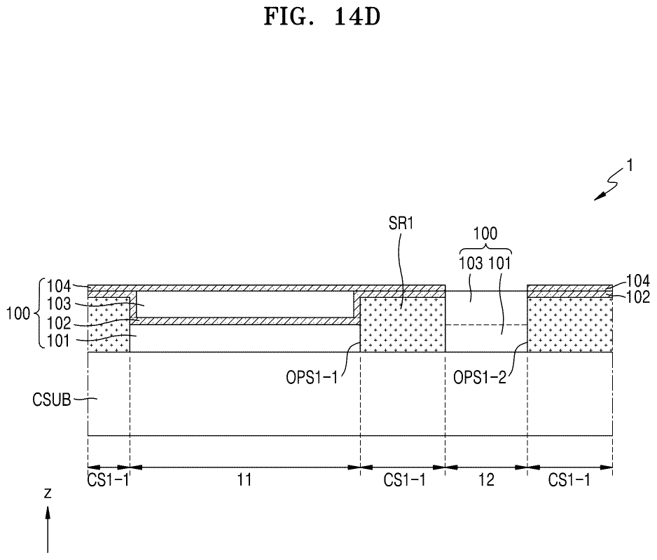

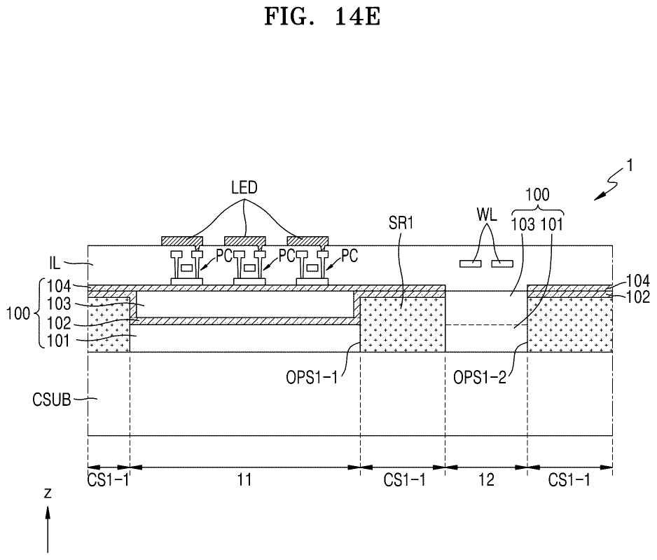

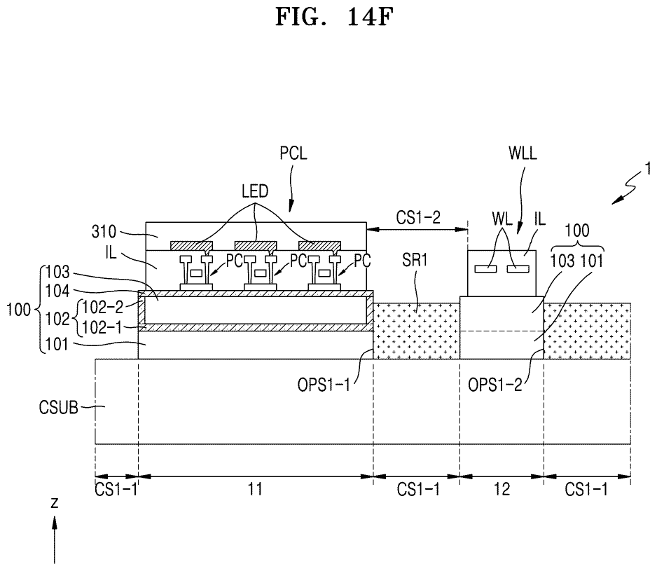

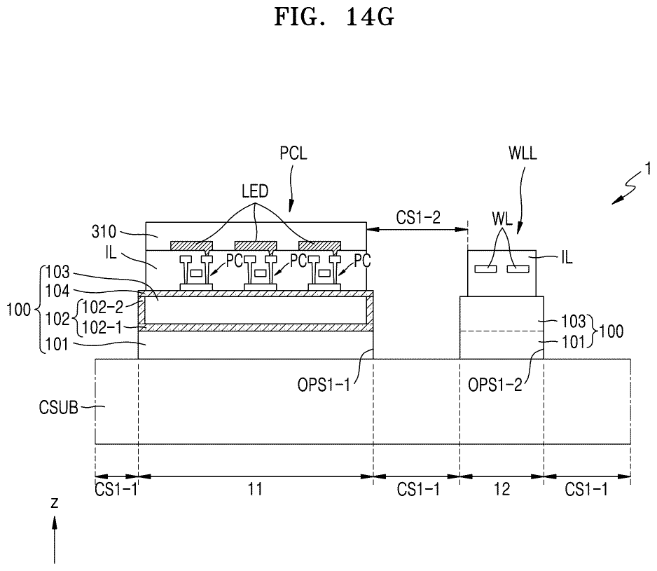

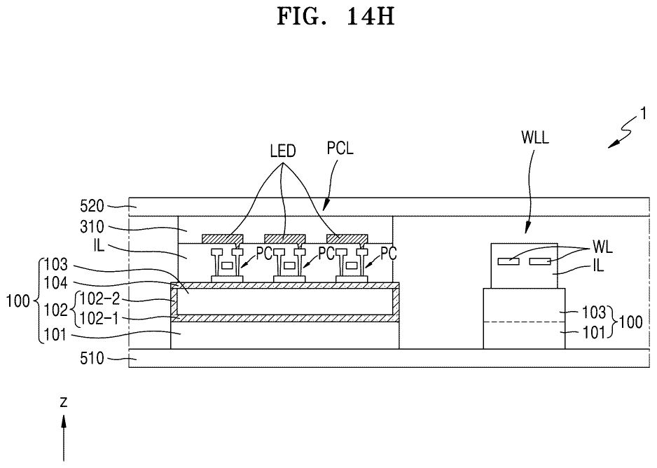

FIG. 13 is a schematic flowchart of the method 2 of manufacturing a display apparatus, according to an embodiment of the present disclosure. FIGS. 14A to 14H are schematic cross-sectional views of the display apparatus 1 according to an embodiment of the present disclosure.

Referring to FIGS. 13 to 14H, the method 2 of manufacturing the display apparatus 1 described with reference to FIG. 12 may be seen.

In FIGS. 13 to 14H, the same reference numerals as those in FIG. 12 denote the same elements, and thus any repetitive detailed descriptions thereof will be omitted or simplified.

First, Referring to FIGS. 13 and 14A, an embodiment of the method 2 of manufacturing a display apparatus may include disposing the first sacrificial layer SR1 on the carrier substrate CSUB (S21).

The first sacrificial layer SR1 may define a first first sacrificial opening portion (hereinafter, will be referred to as “first-1 sacrificial opening portion”) OPS1-1 and a second first sacrificial opening portion (hereinafter, will be referred to as “first-2 sacrificial opening portion”) OPS1-2. In a cross-sectional view, the first-1 sacrificial opening portion OPS1-1 and the first-2 sacrificial opening portion OPS1-2 may be separated (or spaced apart) from each other. In an embodiment, for example, the first sacrificial layer SR1 may include at least one selected from metal ink, metal paste, or liquid silicon. The carrier substrate CSUB may function to support the first sacrificial layer SR1 and a substrate 100 (see FIG. 14F) described below, in the processing process, and may be provided as glass.

Referring to FIGS. 13 and 14B, an embodiment of the method 2 of manufacturing a display apparatus may further include arranging the first base layer 101 within the first-1 sacrificial opening portion OPS1-1 and the first-2 sacrificial opening portion OPS1-2 (S22) and disposing the first barrier layer 102 on the first sacrificial layer SR1 (S23).

In the arranging of the first base layer 101 (S22), the first base layer 101 may be accommodated in each of the first-1 sacrificial opening portion OPS1-1 and the first-2 sacrificial opening portion OPS1-2. The first base layer 101 may be supported by the carrier substrate CSUB. The height of the first base layer 101 may be less than the height of the first sacrificial layer SR1. In the disposing of the first barrier layer 102 (S23), at least a part of the first barrier layer 102 may be arranged within the first-1 sacrificial opening portion OPS1-1. The first barrier layer 102 may cover the first base layer 101 arranged within the first-1 sacrificial opening portion OPS1-1. The first barrier layer 102 may be in contact with an inner circumferential surface of the first sacrificial layer SR1 that defines the first-1 sacrificial opening portion OPS1-1. At this time, the first barrier layer 102 may not be overlapped with the first-2 sacrificial opening portion OPS1-2.

Referring to FIGS. 13 and 14C, an embodiment of the method 2 of manufacturing a display apparatus may further include disposing the second base layer 103 on the first base layer 101 (S24). The second base layer 103 may be arranged within the first-1 sacrificial opening portion OPS1-1 and the first-2 sacrificial opening portion OPS1-2. The second base layer 103 arranged within the first-1 sacrificial opening portion OPS1-1 may be disposed on the first barrier layer 102. The height of the upper surface of the second base layer 103 may be same as the height of the upper surface of the first barrier layer 102. The etching selectivity of the first sacrificial layer SR1 to the first base layer 101 and the second base layer 103 may exceed 1. The first base layer 101 and the second base layer 103 arranged within the first-2 sacrificial opening portion OPS1-2 may form the substrate 100 of a plurality of first bridge portions.

Referring to FIGS. 13 and 14D, an embodiment of the method 2 of manufacturing a display apparatus may further include disposing the second barrier layer 104 on the first barrier layer 102 (S25). In the disposing of the second barrier layer 104 (S25), the second barrier layer 104 may cover the second base layer 103 that is overlapped with the first-1 sacrificial opening portion OPS1-1. The first barrier layer 102 and the second barrier layer 104 may be in contact with each other, and the first barrier layer 102 and the second barrier layer 104 may surround the second base layer 103. At this time, the second barrier layer 104 may not be overlapped with the first-2 sacrificial opening portion OPS1-2. The first base layer 101, the first barrier layer 102, the second base layer 103, and the second barrier layer 104, which are overlapped with the first-1 sacrificial opening portion OPS1-1, may form the substrate 100 of the first island portions 11.

Referring to FIGS. 13, 14E, and 14F, an embodiment of the method 2 of manufacturing a display apparatus may further include disposing the pixel circuit layer PCL on the second barrier layer 104 (S26), disposing the wiring layer WLL on the second barrier layer 104 (S27), etching the second barrier layer 104 (S28), and etching the first barrier layer 102 (S29).

As illustrated in FIG. 14E, the insulating layer IL, the pixel driving circuit portion PC, the wire WL, and the light-emitting element LED may be disposed on the second barrier layer 104 and the second base layer 103.

As illustrated in FIG. 14F, the planarized film 310 may be disposed (or provided) on the insulating layer IL to cover the light-emitting element LED. In an embodiment, for example, the planarized film 310 may include an inorganic insulating material and/or an organic insulating material. In an embodiment, for example, the planarized film 310 may include an inorganic material such as resin and/or urethane epoxy acrylate. In an embodiment, for example, the planarized film 310 may include a photosensitive material, for example, a material such as photoresist.

The insulating layer IL may be etched to form the first-2 opening portion CS1-2 that penetrates the insulating layer IL. The insulating layer IL may be etched by the well-known photolithography process. The etching of the insulating layer IL may be performed in the upper portion of the display apparatus 1 by the dry etching method using the etching gas or the wet etching method using the etching solution. As the insulating layer IL is etched, the pixel circuit layer PCL and the wiring layer WLL may be formed. In other words, the disposing of the pixel circuit layer PCL (S26) and the disposing of the wiring layer WLL (S27) may be simultaneously performed. The pixel circuit layer PCL may be overlapped with the first-1 sacrificial opening portion OPS1-1, and the wiring layer WLL may be overlapped with the first-2 sacrificial opening portion OPS1-2.

The pixel circuit layer PCL and the wiring layer WLL may be separated from each other with the first-2 opening portion CS1-2 therebetween, in a cross-sectional view. At this time, considering the tolerance in the etching process, the width of the first-2 opening portion CS1-2 may be greater than the width of the first sacrificial layer SR1. In other words, the width of the first sacrificial layer SR1 may be less than the width of the first-2 opening portion CS1-2.

A portion of the second barrier layer 104 that is overlapped with the first sacrificial layer SR1 may be etched. The second barrier layer 104 may be etched by the well-known photolithography process. The etching of the second barrier layer 104 may be performed in the upper portion of the display apparatus 1 by the dry etching method using the etching gas or the wet etching method using the etching solution.

A portion of the first barrier layer 102 that is overlapped with the first sacrificial layer SR1 may be etched. The first barrier layer 102 may be etched by the well-known photolithography process. The etching of the first barrier layer 102 may be performed in the upper portion of the display apparatus 1 by the dry etching method using the etching gas or the wet etching method using the etching solution. As the second barrier layer 104 and the first barrier layer 102 are etched, the first sacrificial layer SR1 may be exposed from the second barrier layer 104.

Referring to FIGS. 13, 14F, and 14G, an embodiment of the method 2 of manufacturing a display apparatus may further include removing the first sacrificial layer SR1 (S291).

The first sacrificial layer SR1 may be removed by an etching process. The etching of first sacrificial layer SR1 may be performed in the upper portion of the display apparatus 1 by the dry etching method using the etching gas or the wet etching method using the etching solution. In the etching process of the first sacrificial layer SR1, the first base layer 101 and the second base layer 103 may be hardly etched. As the first sacrificial layer SR1 is etched, the first-1 opening portion CS1-1 may be formed at the location where the first sacrificial layer SR1 was placed.

Referring to FIGS. 13, 14G, and 14H, an embodiment of the method 2 of manufacturing a display apparatus may further include removing the carrier substrate CSUB (S292).

The carrier substrate CSUB may be separated from the substrate 100 by a laser lift-off method of radiating a laser beam onto the lower portion of the carrier substrate CSUB. Alternatively, the carrier substrate CSUB may be separated from the substrate 100 by using the well-known physical or chemical method. As the removing of the carrier substrate CSUB (S292) is substantially the same as that described above with reference to FIGS. 11H to 11J, any repetitive detailed description thereof will be omitted.

When the carrier substrate CSUB is removed, the first encapsulation layer 510 is attached to the lower surface of the substrate 100 by the lamination process, and the second encapsulation layer 520 may be attached to the upper surface of the planarized film 310 by the lamination process. In other words, the substrate 100, the pixel circuit layer PCL, the light-emitting element LED, and the wiring layer WLL may be arranged between the first encapsulation layer 510 and the second encapsulation layer 520.

The first encapsulation layer 510 and the second encapsulation layer 520 may each be formed of a stretchable sheet. The first encapsulation layer 510 may be provided as (or defined by) an elastomer film, a PDMS film, and/or a silicon film. The second encapsulation layer 520 may be formed of (or defined by) a stretchable sheet. The second encapsulation layer 520 may include a same material as that of the first encapsulation layer 510. The second encapsulation layer 520 may be provided as an elastomer film, a PDMS film, and/or a silicon film.

In an embodiment, the etching of the substrate 100 (in detail, the first base layer 101 and the second base layer 103), and the etching of the pixel circuit layer PCL and the wiring layer WLL (in detail, the insulating layer IL), may not be simultaneously performed.

In this process, the substrate 100, the pixel circuit layer PCL and the wiring layer WLL may not be exposed, at one time, to the etching process for a long time. Accordingly, due to the long etching process, the phenomenon that damage is given to the pixel driving circuit portion PC and the wire WL may be reduced. Furthermore, the phenomenon that, after the etching process is completed, a step occurs in the heights of the pixel circuit layer PCL and the wiring layer WLL may be reduced.

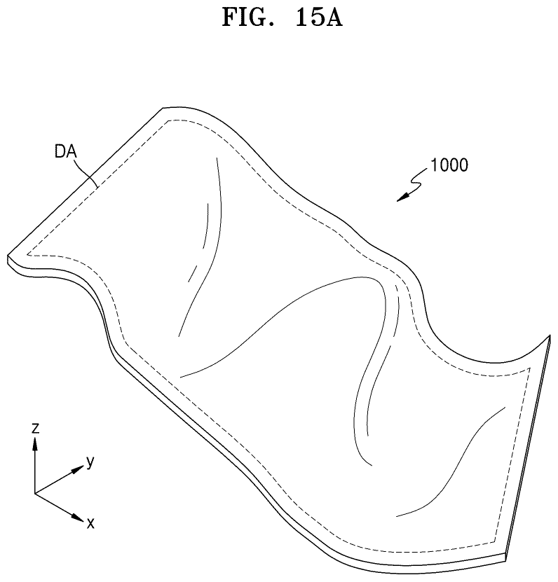

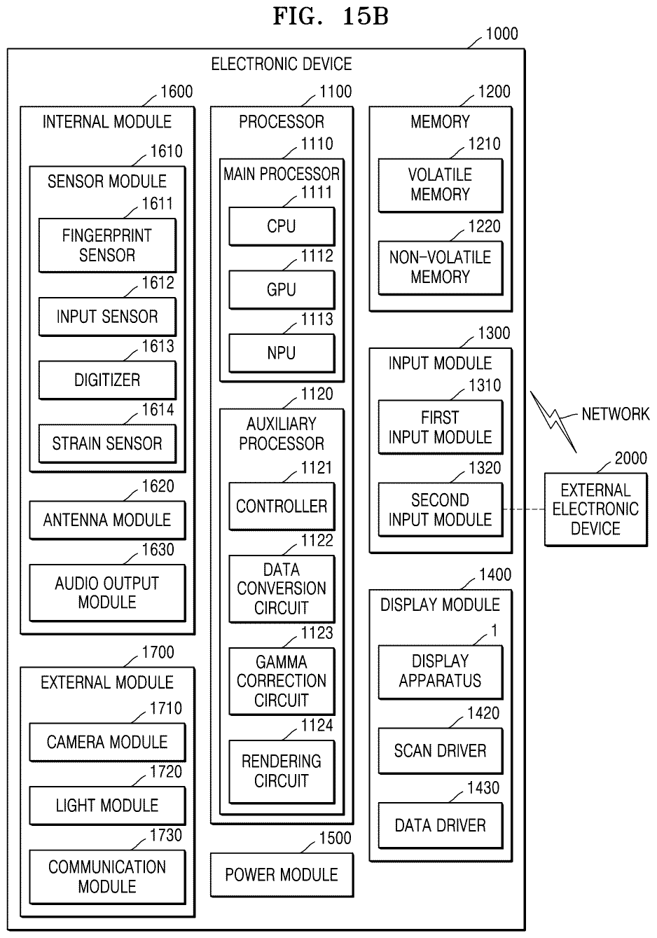

FIG. 15A is a schematic perspective view showing an electronic device 1000 including a display apparatus according to an embodiment. FIG. 15B is a block diagram showing the electronic device 1000 including the display apparatus 1 according to an embodiment.

Referring to FIG. 15A, an embodiment of the electronic device 1000 may be freely deformed in three dimensions, and may provide a three-dimensional image surface through the display area DA. The electronic device 1000 being freely deformed in three dimensions may be distinguished from the operation of an electronic device having a rollable display apparatus, in which, while a part of the display area that is rolled up is being viewed by a user, another part of the display area that has been rolled up is unrolled so that the entire display area is viewed by the user (or while the entire display area that is unrolled is being viewed by a user, the display area is rolled up so that only a part of the display area is viewed by the user). According to the embodiments described above, while the electronic device 1000 is deformed in the x direction, the y direction, and/or the z direction, the electronic device 1000 may be deformed in a way such that the area of the entire display area DA increases or decreases.

Referring to FIG. 15B, an embodiment of the electronic device 1000 may include a processor 1100, a memory 1200, an input module 1300, a display module 1400, a power module 1500, an internal module 1600, and an external module 1700. According to an embodiment, in the electronic device 1000, at least one of the elements described above may be omitted, or one or more other elements may be added. According to an embodiment, some elements (e.g., the internal module 1600) among the elements described above may be integrated into another element (e.g., the display module 1400).

The processor 1100 may execute software to control at least one other element (e.g., a hardware or software element) of the electronic device 1000 connected to the processor 1100 and perform a variety of data processing or operations. According to an embodiment, as at least a part of data processing or operation, the processor 1100 may store, in a volatile memory 1210, commands or data received from another element (e.g., the input module 1300, a sensor module 1610, or a communication module 1730), process the commands or data stored in the volatile memory 1210, and store resulting data in a non-volatile memory 1220.

The processor 1100 may include a main processor 1110 and an auxiliary processor 1120. The main processor 1110 may include at least one selected from a central processing unit (CPU) 1111 or an application processor (AP). The main processor 1110 may further include at least one selected from a graphics processing unit (GPU) 1112, a communication processor (CP), or an image signal processor (ISP). The main processor 1110 may further include a neural processing unit (NPU) 1113. The NPU is a processor specialized for processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of at least two of the networks described above, but the artificial neural network is not limited to the example described above. The artificial intelligence model may include a software structure in addition to or as an alternative to the hardware structure. At least one selected from the processing unit and the processor described above may be implemented as a single integrated configuration (e.g., a single chip), or each of the two may be implemented as an independent configuration (e.g., a plurality of chips).

The auxiliary processor 1120 may include a controller 1121. The controller 1121 may include an interface conversion circuit and a timing control circuit. The controller 1121 may receive an image signal from the main processor 1110, convert a data format of the image signal to fit the interface specifications with the display module 1400, and output the image data. The controller 1121 may output various control signals for driving the display module 1400.

The auxiliary processor 1120 may further include a data processing circuit, such as a data conversion circuit 1122, a gamma correction circuit 1123, or a rendering circuit 1124. The data conversion circuit 1122 may receive image data from the controller 1121, compensate for the image data so that an image is displayed at a desired luminance according to characteristics of the electronic device 1000 or user settings, or convert the image data to reduce power consumption or compensate for afterimages. The gamma correction circuit 1123 may convert image data or a gamma reference voltage so that an image displayed on the electronic device 1000 has desired gamma characteristics. The rendering circuit 1124 may receive the image data from the controller 1121 and render the image data by considering the pixel layout of the display apparatus 1 applied to the electronic device 1000. At least one selected from the data conversion circuit 1122, the gamma correction circuit 1123, or the rendering circuit 1124 may be integrated into another element (e.g., the main processor 1110 or the controller 1121). In an embodiment, the auxiliary processor 1120 may be integrated into a data driver 1430.

The memory 1200 may store various pieces of data which are used by at least one element (e.g., the processor 1100 or the sensor module 1610) of the electronic device 1000, and input data or output data regarding commands related to the various pieces of data. The memory 1200 may include at least one selected from the volatile memory 1210 or the non-volatile memory 1220.

The input module 1300 may receive, from the outside (e.g., a user or an external electronic device 2000)) of the electronic device 1000, commands or data for use in an element (e.g., the processor 1100, the sensor module 1610, or an audio output module 1630) of the electronic device 1000.

The input module 1300 may include a first input module 1310 which receives commands or data from a user, and a second input module 1320 which receives commands or data from the external electronic device 2000.

The first input module 1310 may include a microphone, a mouse, a keyboard, or a pen (e.g., a passive pen or an active pen). The first input module 1310 may include a mechanical input means, such as a button positioned on a rear surface or side surface of the electronic device 1000, a dome switch, a jog wheel, or a jog switch, or a touch input means. The touch input means may include an input detection layer of the display apparatus 1.

The second input module 1320 may be connect, by wire or wirelessly, to the various types of external electronic devices 2000 connected to the electronic device 1000. According to an embodiment, the second input module 1320 may include a high definition multimedia interface (HDMI), a universal serial bus (USB) interface, a Secure Digital (SD) card interface, or an audio interface. The second input module 1320 may include a connector for physically connecting the electronic device 1000 to the external electronic device 2000, for example, an HDMI connector, a USB connector, an SD card connector, or an audio connector (e.g., a headphone connector). In response to the external electronic device 2000 being connected to the second input module 1320, the electronic device 1000 may perform an appropriate control related to the connected external electronic device 2000.

The display module 1400 may provide information visually to a user. The display module 1400 may include the display apparatus 1, a scan driver 1420, and the data driver 1430.

The display apparatus 1 may display (output) information processed in the electronic device 1000. The display apparatus 1 may display execution screen information on an application running on the electronic device 1000, or user interface (UI) or graphic user interface (GUI) information according to the execution screen information.

The scan driver 1420 may be mounted, as a driving chip, in the display apparatus 1. Alternatively, the scan driver 1420 may be formed directly on the display apparatus 1. In an embodiment, for example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG), which is embedded in the display apparatus 1. The scan driver 1420 may receive a control signal from the controller 1121, and output scan signals to the display apparatus 1 in response to the control signal.

The display apparatus 1 may further include an emission control driver. The emission control driver may output an emission control signal to the display apparatus 1 in response to the control signal received from the controller 1121. The emission control driver may be formed distinguished from the scan driver 1420, or may be integrated into the scan driver 1420.

The data driver 1430 may receive a control signal from the controller 1121, convert image data into a data voltage in an analog voltage form in response to the control signal, and then output data voltages to the display apparatus 1.

The data driver 1430 may be integrated into some configurations of the auxiliary processor 1120. In an embodiment, for example, the data driver 1430 may be provided as a timing controller embedded driver integrated circuit (IC) which includes the controller 1121.

The power module 1500 may supply power to elements of the electronic device 1000. The power module 1500 may include a battery which charges a power voltage. In addition, the power module 1500 may include a connection port, and the connection port may be included in the second input module 1320 to which an external charger for supplying power to charge the battery is connected. Alternatively, the power module 1500 may include a wireless power transmission/reception member so as to charge the battery in a wireless manner. The wireless power transmission/reception member may include a plurality of coil-shaped antenna radiators. The power module 1500 may include a power management integrated circuit (PMIC). The PMIC may supply optimized power to each of elements of the electronic device 1000.

The electronic device 1000 may further include the internal module 1600 and the external module 1700. The internal module 1600 may include the sensor module 1610, an antenna module 1620, and the audio output module 1630. The external module 1700 may include a camera module 1710, a light module 1720, and/or the communication module 1730.

The sensor module 1610 may include a touch sensor driving unit and touch electrodes of the input detection layer of the display apparatus 1. The sensor module 1610 may detect an input by a user's body or an input by a pen, and generate an electric signal or data value corresponding to the input. The sensor module 1610 may include at least one selected from a fingerprint sensor 1611, an input sensor 1612, a digitizer 1613, or a strain sensor 1614.

The fingerprint sensor 1611 may generate a data value corresponding to user's fingerprint. The fingerprint sensor 1611 may include any one of an optical fingerprint sensor or a capacitive fingerprint sensor.

The input sensor 1612 may generate a data value corresponding to coordinate information of an input by a user's body or an input by a pen. The input sensor 1612 may generate a data value based on a change in electrostatic capacitance due to an input. The input sensor 1612 may detect an input by a passive pen or transmit/receive data to/from an active pen.

The input sensor 1612 may measure biometric signals, such as blood pressure, water, or body fat. In an embodiment, for example, when a user touches a part of the body to a sensor layer or a sensing panel and does not move for a certain period of time, the input sensor 1612 may detect a biometric signal based on a change in an electric field caused by the body part and output information desired by the user to the display module 1400.

The digitizer 1613 may generate a data value corresponding to coordinate information of an input by a pen. The digitizer 1613 may generate a data value based on an electromagnetic change caused by the input. The digitizer 1613 may detect an input by a passive pen or transmit/receive data to/from an active pen.

The strain sensor 1614 may include layers, patterns, or wires, in which measurable physical quantity changes according to the elongation of the display apparatus 1. In an embodiment, for example, the strain sensor 1614 may include wires with resistance and/or capacitance that changes due to the stretch of the display apparatus 1. In another embodiment, the strain sensor 1614 may include an optical layer or an optical pattern, in which transmittance and/or reflectivity changes due to the elongation of the display apparatus 1.

Based on the physical quantity according to the elongation of the display apparatus 1 measured by the strain sensor 1614, the electronic device 1000 may improve the image quality of an image implemented in the display apparatus 1 or control the display apparatus 1. The control operation of the display apparatus 1 may include, for example, an operation of displaying an operation image for protecting the display apparatus 1, cutting off a voltage for driving the display apparatus 1, or stopping an extension operation of the display apparatus 1.

In an embodiment, at least one selected from the fingerprint sensor 1611, the input sensor 1612, or the digitizer 1613 may be embedded in the display apparatus 1. For example, at least one selected from the fingerprint sensor 1611, the input sensor 1612, or the digitizer 1613 may be formed through a process which is continuous with a process of forming pixel circuits and light-emitting diodes of the display apparatus 1. Due to the above, the display apparatus 1 may function as one of the input modules 1300 which provide an input interface between the electronic device 1000 and the user, while also functioning as the display module 1400 which provides an output interface between the electronic device 1000 and the user.

In an embodiment, at least two selected from the fingerprint sensor 1611, the input sensor 1612, or the digitizer 1613 may be formed to be integrated into one sensing panel through a same process. In an embodiment, the sensing panel may be arranged between the display apparatus 1 and a window which is disposed in an upper portion of the display apparatus 1, but the disclosure is not limited thereto.

The antenna module 1620 may include one or more antennas for transmitting signals or power to the outside or receiving signals or power from the outside. According to an embodiment, the communication module 1730 may transmit signals to an external electronic device or receive signals from the external electronic device through an antenna suitable for a communication scheme. An antenna pattern of the antenna module 1620 may be integrated into a configuration (e.g., the display apparatus 1) of the display module 1400 or the input sensor 1612.

The audio output module 1630, which is a device for outputting audio signals to the outside of the electronic device 1000, may output audio data which is received from the communication module 1730 or stored in the memory 1200 in a call signal reception mode, a call mode or recording mode, a speech recognition mode, or a broadcast reception mode. The audio output module 1630 may output an audio signal related to a function performed in the electronic device 1000 (e.g., call signal reception sound, message reception sound, etc.). The audio output module 1630 may include a receiver and a speaker. At least one selected from the receiver or the speaker may be an audio generation device which is attached to a lower portion of the display apparatus 1 to vibrate the display apparatus 1 and output sound. The audio generation device may be a piezoelectric element or piezoelectric actuator which contracts and expands in response to an electric signal, or an exciter which generates a magnetic force by using a voice coil and vibrates the display apparatus 1.

The camera module 1710 may capture still images and moving images. According to an embodiment, the camera module 1710 may include one or more lenses, an image sensor, or an image signal processor. The camera module 1710 may further include an infrared camera which is capable of measuring the presence or absence of a user, a user's position, a user's gaze, or the like.

The light module 1720 may output a signal to notify the occurrence of an event by using light from a light source, or provide light for image acquisition. Here, examples of the event occurrence may include receiving a message, receiving a call signal, missing a call, an alarm, a schedule reminder, receiving an e-mail, or notifying battery charge capacity information. The light module 1720 may include a light-emitting diode or a xenon lamp. The light module 1720 may emit light of a single color or multiple colors to a front surface or rear surface of the electronic device 1000. The light module 1720 may be operate in conjunction with or independently of the camera module 1710.

The communication module 1730 may support establishment of a wired or wireless communication channel between the electronic device 1000 and the external electronic device 2000, and performing of a communication through the established communication channel. The communication module 1730 may include any one or all of a wireless communication module, such as a cellular communication module, a short-range wireless communication module, or a global navigation satellite system (GNSS) communication module, a local area network (LAN) communication module, or a wired communication module, such as a power line communication module. The communication module 1730 may transmit/receive wireless signals on the Internet by using at least one selected from wireless LAN (WLAN), wireless-fidelity (Wi-Fi), Wi-Fi direct, or digital living network alliance (DLNA) technologies. In addition, the communication module 1730 may support short-range communication by using at least one selected from Bluetooth™, radio frequency identification (RFID), infrared data association (IrDA), ultra-wideband (UWB), ZigBee, near field communication (NFC), Wi-Fi, Wi-Fi direct, or wireless USB technologies. The communication modules 1730 of various types described above may be implemented as one chip or as separate chips.

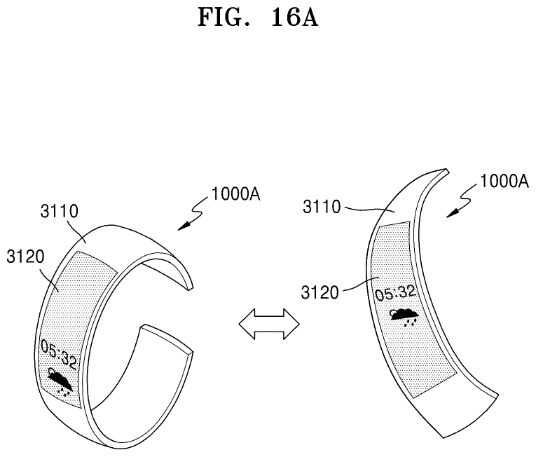

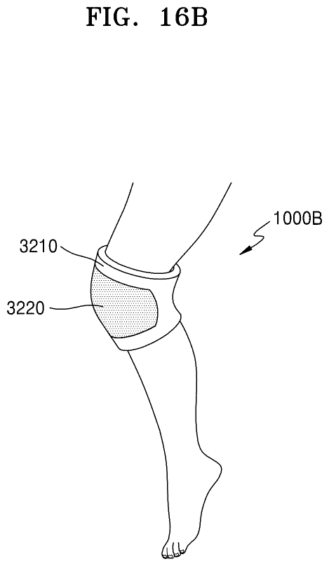

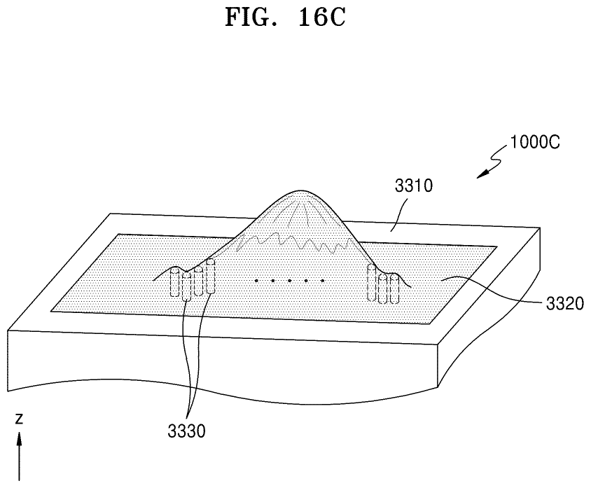

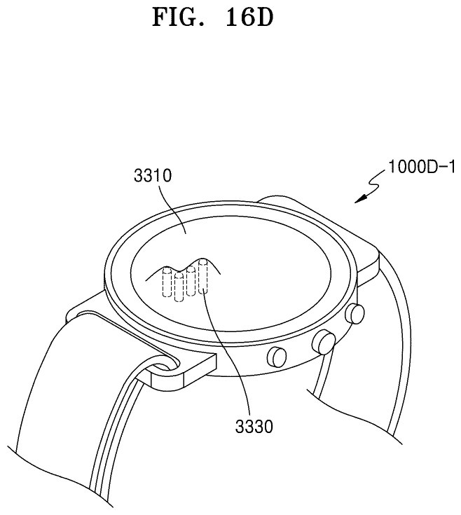

FIGS. 16A to 16D are each a perspective view schematically illustrating embodiments of an electronic device including a display apparatus according to an embodiment of the present disclosure.

Referring to FIG. 16A, an embodiment of the display apparatuses described above may be used for a wearable electronic device 1000A that is wearable in a part of a user's body. The wearable electronic device 1000A may include a body part 3110 and a display part 3120 provided in the body part 3110. The display apparatuses according to the embodiments described above may be used as the display part 3120 of the wearable electronic device 1000A. As illustrated in FIG. 16A, the wearable electronic device 1000A may be deformable. In an embodiment, the wearable electronic device 1000A may be used as a smart watch or a smartphone according to the user's selection.

FIG. 16B illustrates a medical electronic device 1000B. In an embodiment, the medical electronic device 1000B may include a body part 3210 and an emission unit 3220. An embodiment of the display apparatuses described above may be used as the emission unit 3220 of the medical electronic device 1000B. The emission unit 3220 may emit light (e.g., infrared, visible light, etc.) of a certain wavelength band to the body of a patient. In an embodiment, the body part 3210 may include a stretchable textile material, and may have a structure to be worn on the body of a user using the emission unit 3220.

FIG. 16C illustrates an educational electronic device 1000C. In an embodiment, the educational electronic device 1000C may include a display part 3320 provided in a frame 3310. The display part 3320 may use an embodiment of the display apparatuses described above. Images such as a sea with crashing waves, a snow-covered mountain, or a volcano with flowing lava may be provided through the display part 3320, and in this state, the display part 3320 may be stretched in a height direction (e.g., the z direction) by reflecting the height of the waves, the mountain, or the volcano. In some embodiments, a part of the display part 3320 has a height that sequentially varies depending on a direction in which lava flows, thereby showing the movement of lava in three dimensions. The educational electronic device 1000C may include a plurality of pins (or strokes parts 3330) arranged on the rear surface of the display part 3320 to cause the display part 3320 to be stretched in the height direction. As the pins 3330 move in the third direction (e.g., the z direction or the −z direction), the image displayed in the display part 3320 may be implemented to have a height in three dimensions. Although FIG. 16C illustrates an example of the educational electronic device 1000C, any device capable of providing certain image information may be used therefor and the use of the device is not limited thereto.

FIG. 16D illustrates an embodiment where a display apparatus is used in a wearable electronic device 1000D-1 such as a smart watch. In an embodiment, the display apparatus corresponding to a display part 3310 of the wearable electronic device 1000D-1 is three-dimensionally stretchable so as to provide a user with various pieces of haptic information. In an embodiment, the electronic device 1000D-1 may provide haptic information, such as tactile stimulation in conjunction with an image, or a Braille display for the visually impaired, by using a plurality of pins (or the stroke parts 3330) arranged below the display part 3310. The display apparatus forming the display part 3310, which is stretchable three-dimensionally, may provide a user with the haptic information described above.

The embodiments described with reference to FIGS. 16A to 16D describe that the display part may be the electronic devices 1000A, 1000B, 1000C, and 1000D-1 that are three-dimensionally deformable, but the disclosure is not limited thereto. As in the embodiments described below, the display apparatus according to the embodiments of the present disclosure maybe used in an electronic device in which the shape of a portion (e.g., a screen) that can express an image is fixed.

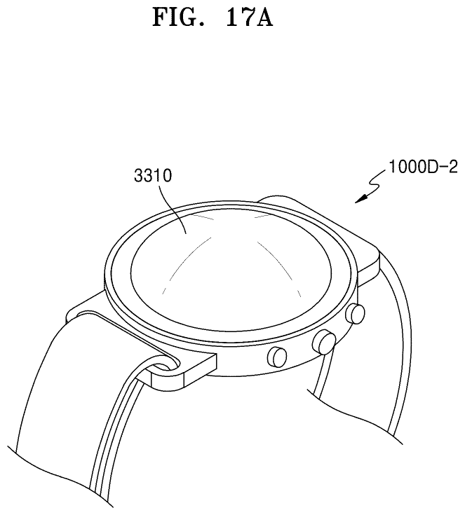

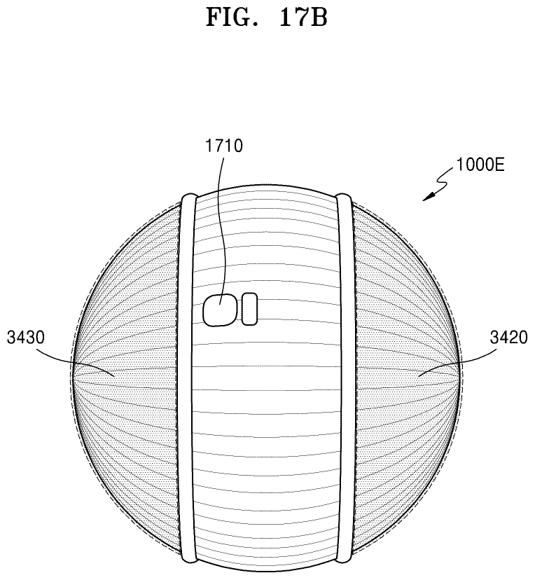

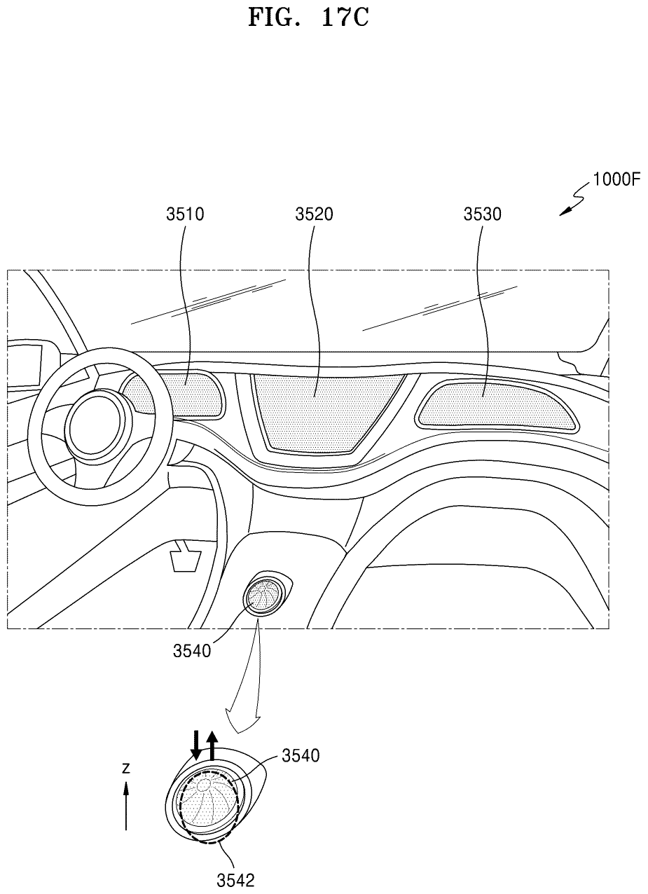

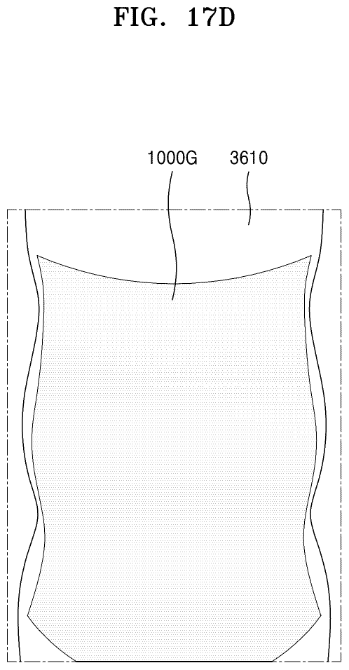

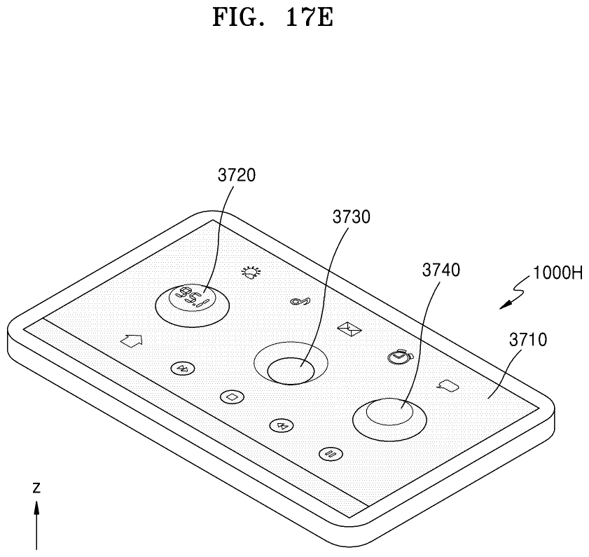

FIGS. 17A to 17E are each a perspective view schematically illustrating an electronic device according to an embodiment of the present disclosure.

FIG. 17A illustrates an embodiment where the display apparatus is used in a wearable electronic device 1000D-2 such as a smart watch. The electronic device 1000D-2 illustrated in FIG. 17A may include the display part 3310, and the display part 3310 may have a three-dimensional dome shape (or a hemispherical shape). In the process of manufacturing the electronic device 1000D-2, the display apparatus may be assembled on a dome-shaped body frame, and at this time, as the display apparatus is three-dimensionally stretchable, the display apparatus may be assembled in a stretched state following the shape of a hemispherical body frame.

FIG. 17B illustrates an electronic device 1000E according to an embodiment of the present disclosure including a robot. The robot may recognize a movement or an object by using a camera module 1710, and display a certain image to a user through display parts 3420 and 3430. In some embodiments, as the display apparatuses according to the embodiments of the present disclosure is stretchable in various directions as described above, the display apparatus may be assembled to a body frame having a hemispherical shape, and thus, the robot may include the display parts 3420 and 3430 that are hemispherical.

FIG. 17C illustrates a vehicle display device 1000F as an electronic device according to an embodiment of the present disclosure. The vehicle display device 1000F may include a cluster 3510, a center information display (CID) 3520, and/or a co-driver display 3530. As the display apparatus according to the embodiment of the present disclosure is stretchable in various directions, regardless of the shape of an internal frame of a vehicle, the display apparatus may be used for the cluster 3510, the CID 3520, and/or a co-driver display 3530.

Although FIG. 17C illustrates an embodiment where the cluster 3510, the CID 3520, and/or the co-driver display 3530 are separated from one another, the present disclosure is not limited thereto. In another embodiment, two or more components selected from among the cluster 3510, the CID 3520, and/or the co-driver display 3530 may be connected integrally.

In some embodiments, the vehicle display device 1000F may include a button 3540 that is capable of displaying a certain image. Referring to the enlarged portion of FIG. 17C, the button 3540 that is hemispherical may include an object 3542 that moves in the z direction or the −z direction and provides a sense of using a button and a display apparatus arranged above the object 3542. In some embodiments, when the object 3542 has a three-dimensionally rounded surface, the display apparatus may have a three dimensionally further rounded surface.

FIG. 17D illustrates a case where an electronic device according to an embodiment of the present disclosure is an electronic device 1000G for advertising or display. In some embodiments, the electronic device 1000G for advertising or display may be installed on a structure 3610 that is fixed, such as a wall or a pillar. In an embodiment where the structure 3610 includes an uneven surface as illustrated in FIG. 17D, the electronic device 1000G for advertising or display may be arranged along the uneven surface of the structure 3610. In some embodiments, the electronic device 1000G for advertising or display may be installed on the structure 3610 by using a heat shrink film or the like.

FIG. 17E illustrates an electronic device 1000H according to an embodiment of the present disclosure as a controller. The controller may include an image type button. In an embodiment, for example, the controller may include first to third button areas 3720, 3730, and 3740 formed as partial areas of a display part 3710 protrude in the z direction or in the −z direction (or recessed in the z direction). In some embodiments, the first and third button areas 3720 and 3740 may protrude in the z direction, and the second button area 3730 may protrude in the −z direction (or recessed in the z direction).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit and scope of the invention as defined by the following claims.

What is claimed is:

1. A display apparatus comprising a plurality of first island portions and a plurality of first bridge portions connecting the plurality of first island portions to each other, the display apparatus comprising:
a substrate comprising a base layer overlapping each of the plurality of first island portions and the plurality of first bridge portions;
a first mask layer disposed on the base layer to overlap the plurality of first island portions;
a pixel circuit layer disposed on the first mask layer;
a wiring layer disposed on the base layer to overlap the plurality of first bridge portions; and
a light-emitting element disposed on the pixel circuit layer.

2. The display apparatus of claim 1, wherein the substrate further comprises a barrier layer disposed on the first mask layer.

3. The display apparatus of claim 1, wherein a width of the first mask layer is greater than a width of the pixel circuit layer.

4. The display apparatus of claim 1, further comprising a second mask layer disposed on the base layer to overlap the plurality of first bridge portions.

5. The display apparatus of claim 4, wherein the first mask layer and the second mask layer are arranged in a same layer as each other.

6. The display apparatus of claim 4, wherein the first mask layer and the second mask layer comprise a same material as each other.

7. The display apparatus of claim 4, wherein a width of the second mask layer is greater than a width of the wiring layer.

8. A display apparatus comprising a plurality of first island portions, and a plurality of first bridge portions connecting the plurality of first island portions to each other, the display apparatus comprising:
a substrate;
a pixel circuit layer disposed on the substrate to overlap the plurality of first island portions;
a wiring layer disposed on the substrate to overlap the plurality of first bridge portions; and
a light-emitting element disposed on the pixel circuit layer,
wherein the substrate comprises:
a first base layer overlapping the plurality of first island portions;
a first barrier layer disposed on the first base layer;
a second base layer disposed on the first barrier layer; and
a second barrier layer disposed on the second base layer, and
the first barrier layer and the second barrier layer surround the second base layer.

9. The display apparatus of claim 8, wherein the first barrier layer comprises:
a first first barrier portion supporting a lower surface of the second base layer; and
a second first barrier portion extending from the first first barrier portion toward the second barrier layer and surrounding the second base layer.

10. The display apparatus of claim 9, wherein the second first barrier portion and the second barrier layer are in contact with each other.

11. The display apparatus of claim 9, wherein the second base layer is accommodated in the second first barrier portion.

12. The display apparatus of claim 8, wherein a width of the second barrier layer is greater than a width of the pixel circuit layer.

13. An electronic device comprising a display apparatus which is stretchable and includes a plurality of first island portions and a plurality of first bridge portions connecting the plurality of first island portions to each other,
wherein the display apparatus comprises:
a substrate comprising a base layer overlapping each of the plurality of first island portions and the plurality of first bridge portions;
a first mask layer disposed on the base layer to overlap the plurality of first island portions;
a pixel circuit layer disposed on the first mask layer;
a wiring layer disposed on the base layer to overlap the plurality of first bridge portions; and
a light-emitting element disposed on the pixel circuit layer.

14. A method of manufacturing a display apparatus, the method comprising:
disposing a base layer on a carrier substrate;
disposing a first mask layer on the base layer;
disposing a second mask layer on the base layer to be spaced apart from the first mask layer in a cross-sectional view;
forming a first first opening portion and a second first opening portion in the base layer, by etching a portion of the base layer which is not overlapped with the first mask layer and the second mask layer;
arranging a first sacrificial layer within the first first opening portion;
disposing a barrier layer on the first mask layer;
disposing a pixel circuit layer on the barrier layer;
disposing a wiring layer on the base layer to be spaced apart from the pixel circuit layer with the second first opening portion therebetween, in a cross-sectional view;
removing the first sacrificial layer; and
removing the carrier substrate.

15. The method of claim 14, further comprising etching a portion of the barrier layer which is overlapped with the first first opening portion.

16. The method of claim 14, wherein the disposing of the pixel circuit layer and the disposing of the wiring layer are simultaneously performed.

17. The method of claim 14, wherein a width of the first first opening portion is less than a width of the second first opening portion.

18. A method of manufacturing a display apparatus, the method comprising:
disposing a first sacrificial layer on a carrier substrate, wherein the first sacrificial layer defines a first first sacrificial opening portion and a second first sacrificial opening portion;
arranging a first base layer within the first first sacrificial opening portion and the second first sacrificial opening portion;
disposing a first barrier layer on the first sacrificial layer in a way such that at least a part of the first barrier layer is arranged within the first first sacrificial opening portion;
disposing a second base layer on the first base layer to be arranged within the first first sacrificial opening portion and the second first sacrificial opening portion;
disposing a second barrier layer on the first barrier layer to cover a portion of the second base layer which is overlapped with the first first sacrificial opening portion;
disposing a pixel circuit layer on the second barrier layer to overlap the first first sacrificial opening portion;
disposing a wiring layer on the second barrier layer to overlap the second first sacrificial opening portion;
removing the first sacrificial layer; and
removing the carrier substrate.

19. The method of claim 18, wherein, in the disposing of the first barrier layer, the first barrier layer is in contact with an inner circumferential surface of the first sacrificial layer which defines the first first sacrificial opening portion.

20. The method of claim 18, wherein, in the disposing of the second barrier layer, the first barrier layer and the second barrier layer are in contact with each other, and
the first barrier layer and the second barrier layer surround the second base layer.
